(19) United States
(12) Patent Application Publication
(10) Pub. No.: US 2026/0368377 A1
(43) Pub. Date: Nov. 19, 2026

(54) ELECTRONIC DEVICE FOR PROVIDING A 3D MODEL EDITED BASED ON USER INPUT, OPERATING METHOD THEREOF, AND RECORDING MEDIUM FOR PERFORMING THE METHOD

(71) Applicant: THE DIMENSION COMPANY, Seo-gu (KR)

(72) Inventor: Re LEE, Hwaseong-si (KR)

(21) Appl. No.: 19/433,338

(22) Filed: Dec. 26, 2025

(30) Foreign Application Priority Data
May 13, 2025 (KR) 10-2025-0061936
Aug. 22, 2025 (KR) 10-2025-0117124
Aug. 22, 2025 (KR) 10-2025-0117128
Aug. 22, 2025 (KR) 10-2025-0117148
Aug. 22, 2025 (KR) 10-2025-0117150

(51) Int. Cl. G06F 30/12; G06F 30/27

(52) U.S. Cl. CPC G06F 30/12; G06F 30/27

(57) ABSTRACT

The electronic device may display, via a user device, a first screen including a first area including a first 3D model generated based on a first CAD Representation and a second area including a user prompt, obtain a first user input for editing at least one first design element of the first 3D model via at least one of the first area and the second area, wherein the first design element includes at least one of one or more parts or one or more portions constituting the first 3D model, obtain a second CAD Representation in which the first CAD Representation is edited based on the first user input, obtain a second 3D model visualized by rendering the second CAD Representation, and display, via the user device, a second screen displaying the visualized second 3D model in the first area. Various other embodiments may be derived from the specification.

### CROSS-REFERENCE TO RELATED APPLICATION

This application claims priority to and the benefit of Korean Patent Application No. 10-2025-0061936, filed on MAY 13, 2025, Korean Patent Application No. 10-2025-0117128, filed on AUG. 22, 2025, Korean Patent Application No. 10-2025-0117124, filed on AUG. 22, 2025, Korean Patent Application No. 10-2025-0117148, filed on AUG. 22, 2025, Korean Patent Application No. 10-2025-0117150, filed on AUG. 22, 2025, the disclosures of which are incorporated herein by reference in its entirety.

### BACKGROUND

### Field of the Invention

Various embodiments disclosed herein relate to an electronic device that provides a 3D model edited based on user input, a method of operating the same, and a recording medium for performing the method.

### Discussion of Related Art

With the recent advancement of artificial intelligence technology, various attempts have been made to generate three-dimensional (3D) models from text, images, and the like.

Representative conventional 3D model generation technologies include technologies in which a diffusion model widely used for two-dimensional image generation is extended to a three-dimensional space, or Neural Radiance Fields (NeRF) technologies that render a three-dimensional scene from a set of two-dimensional images captured from multiple angles. However, these technologies mainly generate results in the form of a polygon mesh, a voxel, or a point cloud. Models generated by such technologies have limitations in that surfaces are uneven, numerical accuracy is difficult to guarantee, and partial editing or control, such as selecting a specific portion of a model and changing a shape thereof, is difficult. Accordingly, these technologies have had difficulty being directly utilized in production and design fields of actual industrial sites.

Meanwhile, in industrial sites, traditional Computer-Aided Design (CAD) software is widely used. Since CAD software mathematically represents shapes using schemes such as Boundary Representation (B-rep) or Constructive Solid Geometry (CSG), it has advantages in enabling precise modeling and design. However, CAD software requires experts to learn complex functions and command systems and to manually design all shapes. As a result, a long time is required to learn and master the software, working time and cost significantly increase when implementing complex shapes, and design flexibility is reduced due to numerous geometric and numerical constraints.

The above information may be provided as related art for helping understanding of the present disclosure. No assertion or determination is made as to whether any of the above-described content may be applied as prior art with respect to the present disclosure.

### SUMMARY OF THE INVENTION

Conventional AI-based 3D modeling technologies are easy to use but have problems in that precision of results and ease of editing are insufficient. In addition, traditional CAD technologies have high precision of results but have problems in that they are difficult for general users to use and have low working efficiency.

Accordingly, there is a need for a technology capable of automatically generating a three-dimensional model that is precise and easy to edit enough to be utilized in actual design and production, while allowing even non-experts to easily and quickly implement ideas.

Various embodiments disclosed herein provide an electronic device for generating a more intuitive and accurate 3D model based on a simple text prompt input and additional user input capable of reflecting a user’s detailed intent.

Various embodiments disclosed herein are intended to solve problems in that mesh- or voxel-based 3D models generated by conventional AI technologies are difficult to partially edit and modify. Accordingly, the embodiments provide an electronic device capable of generating and editing a CAD Representation itself including mathematical and structural information, rather than a rendered 3D model.

Various embodiments disclosed herein provide an electronic device capable of selecting and editing specific design elements constituting a generated 3D model, that is, detailed regions in units of parts or portions.

Various embodiments disclosed herein provide an electronic device that enhances user experience (UX) so that a user can clearly recognize and control changes during an editing process of a complex 3D model.

Various embodiments disclosed herein provide an electronic device capable of generating multiple 3D models based on a single user input. Accordingly, a user can improve efficiency of a design process.

Various embodiments disclosed herein provide an electronic device that provides visualization information allowing a user to understand a design intent and a structure of a model, rather than a “black-box” type 3D model that only shows a final result. The embodiments provide design visualization information, such as internal and external structures of parts constituting a 3D model or assembly relationships thereof, to a user based on design information inherent in a CAD Representation.

According to various embodiments, an electronic device may include a communication circuit configured to transmit and receive data with a user device, at least one processor, and a memory storing instructions, wherein the instructions are executed individually or collectively by the at least one processor to cause the electronic device to display, via the user device, a first screen including a first area including a first 3D model generated based on a first CAD Representation and a second area including a user prompt, obtain a first user input for editing at least one first design element of the first 3D model via at least one of the first area and the second area, wherein the first design element includes at least one of one or more parts or one or more portions constituting the first 3D model, obtain a second CAD Representation in which the first CAD Representation is edited based on the first user input, obtain a second 3D model visualized by rendering the second CAD Representation, and display, via the user device, a second screen displaying the visualized second 3D model in the first area.

According to various embodiments, a method of operating an electronic device may include displaying, via a user device, a first screen including a first area including a first 3D model generated based on a first CAD Representation and a second area including a user prompt, obtaining a first user input for editing at least one first design element of the first 3D model via at least one of the first area and the second area, wherein the first design element includes at least one of one or more parts or one or more portions constituting the first 3D model, obtaining a second CAD Representation in which the first CAD Representation is edited based on the first user input, obtaining a second 3D model visualized by rendering the second CAD Representation, and displaying, via the user device, a second screen displaying the visualized second 3D model in the first area.

According to various embodiments, an electronic device may include a display, at least one processor, and a memory storing instructions, wherein the instructions are executed individually or collectively by the at least one processor to cause the electronic device to display, via the display, a first screen including a first area including a first 3D model generated based on a first CAD Representation and a second area including a user prompt, obtain a first user input for editing at least one first design element of the first 3D model via at least one of the first area and the second area, wherein the first design element includes at least one of one or more parts or one or more portions constituting the first 3D model, obtain a second CAD Representation in which the first CAD Representation is edited based on the first user input, obtain a second 3D model visualized by rendering the second CAD Representation, and display, via the display, a second screen displaying the visualized second 3D model in the first area.

According to various embodiments disclosed herein, a user can easily and quickly implement an idea as a precise three-dimensional (3D) model even without expert knowledge of Computer-Aided Design (CAD). For example, by receiving a 3D model generated based not only on a text input but also on additional user input, a user can be provided with a 3D model that accurately reflects a user’s detailed intent.

According to various embodiments disclosed herein, unlike mesh- or voxel-based models generated by conventional AI technologies, a user of an electronic device can generate a precise and easily editable 3D model at a level directly usable in design and production of actual industrial sites through an artificial intelligence model trained to generate a CAD Representation including mathematical and structural information.

According to various embodiments disclosed herein, a user of an electronic device can designate specific design elements constituting a generated 3D model, that is, one or more parts or portions, as editing targets, and obtain a new 3D model by editing the CAD Representation itself based on input for the designated elements, thereby quickly modifying only desired portions without regenerating an entire model and maximizing design flexibility.

According to various embodiments disclosed herein, a user of an electronic device can be provided with an intuitive user experience (UX) by confirming that a design element to be edited is visually distinguished during an editing process and that a changed portion is displayed as a separate visual object after editing is completed, thereby clearly recognizing and controlling changes.

According to various embodiments disclosed herein, a user of an electronic device can request generation of a plurality of 3D models with a single request and can be simultaneously provided with a plurality of precisely generated 3D models, thereby efficiently exploring various design alternatives and improving efficiency of a design process.

According to various embodiments disclosed herein, a user of an electronic device can deeply understand and verify a design intent and a structure of a model by being provided with design visualization information, such as internal and external structures of parts constituting the model or assembly relationships thereof, based on design information extracted from a CAD Representation, beyond a simple shape of a generated 3D model.

In addition, various effects that are directly or indirectly recognized through the present disclosure may be provided.

### BRIEF DESCRIPTION OF THE DRAWINGS

FIG. 1 is a diagram illustrating interaction with an external system according to various embodiments.

FIG. 2 is a diagram illustrating a physical configuration according to various embodiments.

FIG. 3 is an internal functional block diagram of an electronic device according to various embodiments.

FIG. 4 is a block diagram of a structured command according to various embodiments.

FIG. 5 is a flowchart illustrating an operation in which an electronic device provides a 3D model based on user input according to various embodiments.

FIG. 6A is a diagram illustrating a user interface for obtaining user input according to various embodiments.

FIG. 6B is a diagram illustrating a user interface for displaying a 3D model generated according to user input according to various embodiments.

FIG. 7A is a diagram for explaining that an electronic device generates a 3D model based on user input according to various embodiments.

FIG. 7B is a diagram for explaining that an electronic device displays a 3D model based on position information according to various embodiments.

FIG. 8 is a flowchart illustrating an operation in which an electronic device displays a 3D model based on position information according to various embodiments.

FIG. 9 is a diagram illustrating a user interface for displaying a 3D model in a virtual design space according to various embodiments.

FIG. 10 is a flowchart illustrating an operation in which an electronic device provides an edited 3D model based on user input according to various embodiments.

FIG. 11A is a diagram illustrating a user interface for obtaining user input for editing a 3D model according to various embodiments.

FIG. 11B is a diagram illustrating a user interface for displaying a 3D model edited according to user input according to various embodiments.

FIG. 12 is a diagram for explaining that an electronic device edits a 3D model based on user input according to various embodiments.

FIG. 13A is a diagram illustrating one example of various user interfaces for editing a 3D model according to various embodiments.

FIG. 13B is a diagram illustrating one example of various user interfaces for editing a 3D model according to various embodiments.

FIG. 14 is a flowchart illustrating an operation in which an electronic device provides a screen displaying an edited 3D model according to various embodiments.

FIG. 15 is a diagram illustrating one example of various user interfaces for displaying an edited 3D model according to various embodiments.

FIG. 16 is a flowchart illustrating an operation in which an electronic device provides a plurality of 3D models based on user input according to various embodiments.

FIG. 17 is a diagram for explaining that an electronic device generates a plurality of CAD Representations based on user input according to various embodiments.

FIG. 18 is a diagram for explaining that an electronic device provides a plurality of 3D models based on a plurality of CAD Representations according to various embodiments.

FIG. 19 is a diagram for explaining that an electronic device arranges a plurality of 3D models according to various embodiments.

FIG. 20 is a flowchart illustrating an operation in which an electronic device provides design information for a 3D model according to various embodiments.

FIG. 21 is a diagram illustrating one example of various user interfaces for displaying design information of a 3D model according to various embodiments.

FIG. 22 is a flowchart illustrating an operation in which an electronic device provides design information for a part of a 3D model according to various embodiments.

FIG. 23 is a diagram illustrating one example of various user interfaces for displaying design information for a part of a 3D model according to various embodiments.

With respect to the description of the drawings, the same or similar reference numerals may be used to denote the same or similar components.

### DETAILED DESCRIPTION OF EXEMPLARY EMBODIMENTS

Various structural and/or functional descriptions for various embodiments are merely exemplified for the purpose of description according to various embodiments, and various embodiments may be implemented in various forms and should not be construed as being limited to the embodiments described in the present specification or application.

Since various embodiments may have various modifications and various forms, various embodiments are illustrated in the drawings and described in detail in the present specification or application. However, matters disclosed from the drawings are not intended to specify or limit various embodiments, and should be understood to include all modifications, equivalents, and substitutes falling within the spirit and technical scope of various embodiments.

Terms such as “first” and/or “second” may be used to describe various components, but the components should not be limited by such terms. Such terms are only used to distinguish one component from another component. For example, without departing from the scope of rights according to the concept of the present disclosure, a first component may be named a second component, and similarly, a second component may also be named a first component.

When it is mentioned that a component is “connected to” or “coupled to” another component, it should be understood that the component may be directly connected to or coupled to the other component, or one or more intermediate components may exist therebetween. In contrast, when it is mentioned that a component is “directly connected to” or “directly coupled to” another component, it should be understood that no intermediate component exists therebetween. Other expressions describing a relationship between components, such as “between” and “directly between,” or “adjacent to” and “directly adjacent to,” should be interpreted in the same manner.

The terms used herein are used only for the purpose of describing particular embodiments and are not intended to limit various embodiments. The singular forms include the plural forms unless the context clearly indicates otherwise. As used herein, the terms “include,” “including,” “comprise,” “comprising,” “have,” and “having” specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meaning as commonly understood by one of ordinary skill in the art to which the present disclosure pertains. Terms such as those defined in commonly used dictionaries should be interpreted as having meanings consistent with their meanings in the context of the related art, and are not to be interpreted in an idealized or overly formal sense unless expressly defined herein.

The singular forms should be understood to include plural forms unless the context clearly indicates otherwise, and the terms “include” or “have” are intended to specify the presence of implemented features, numbers, steps, operations, components, parts, or combinations thereof, and should be understood not to preclude the presence or addition of one or more other features, numbers, steps, operations, components, parts, or combinations thereof.

In each step, identification symbols (e.g., a, b, c, and the like) are used for convenience of description and do not describe an order of the steps, and the steps may occur in an order different from the order described unless a particular order is clearly stated in the context. That is, the steps may occur in the same order as described, may be performed substantially simultaneously, or may be performed in the reverse order.

The present disclosure may be implemented as computer-readable code on a computer-readable recording medium, and the computer-readable recording medium includes any type of recording device in which data readable by a computer system is stored. Examples of the computer-readable recording medium include ROM, RAM, CD-ROM, magnetic tape, floppy disk, optical data storage devices, and the like, and also include those implemented in the form of a carrier wave (e.g., transmission through the Internet). In addition, the computer-readable recording medium may be distributed in network-connected computer systems such that computer-readable code is stored and executed in a distributed manner.

Hereinafter, preferred embodiments of the present disclosure will be described in detail with reference to the accompanying drawings. The same reference numerals used in the drawings denote the same elements.

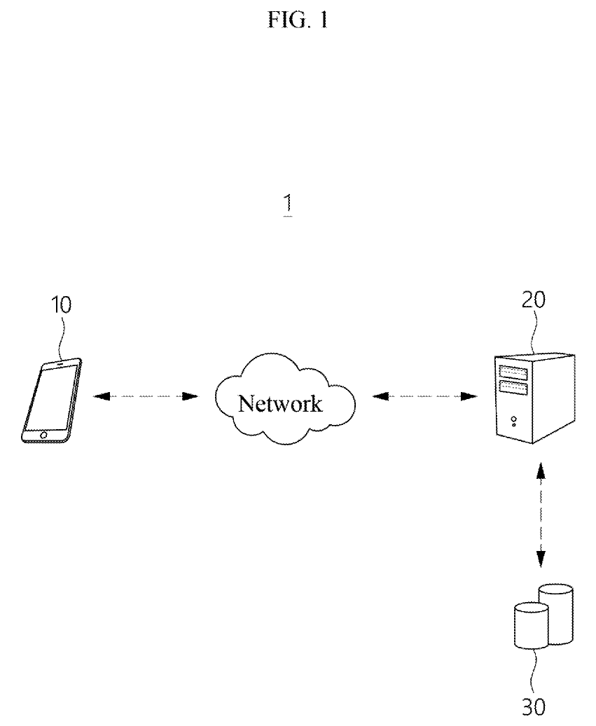

FIG. 1 is a diagram illustrating a system of the present disclosure according to one embodiment.

Referring to FIG. 1, a system 1 may include a user device 10, an electronic device 20, and a database 30.

The user device 10 may be a device capable of checking data generated through the electronic device 20 and metadata obtained by analyzing the data, and may be a device including a display device (e.g., a display). For example, the user device 10 may be implemented as a mobile phone, a smartphone, a personal digital assistant (PDA), a notebook computer, a television (TV), a wearable device, or a head mounted device (HMD). However, the user device 10 is not limited thereto and may be implemented as various devices. The user device 10 may be connected to the electronic device 20 through a network, and a plurality of user devices 10 may be simultaneously connected to the electronic device 20.

According to various embodiments, the user device 10 may include various input devices capable of obtaining user input from a user. For example, the user device 10 may include at least one of a keyboard, a touch pad, a key (e.g., a button), a mouse, a microphone, or a digital pen (e.g., a stylus pen).

According to various embodiments, the system 1 may include any of various wireless communication networks suitable for coupling the electronic device 20 and the user device 10 to communicate with each other. For example, the system 1 may include WLAN, WAN, PAN, cellular, WMN, WiMAX, GAN, 6LowPAN, and the like.

The electronic device 20 may include an Agent-based three-dimensional model generation apparatus. The electronic device 20 may be provided in a computer-readable recording medium by tangibly implementing a program of instructions for implementing the same. In other words, the electronic device 20 may be implemented in the form of program instructions executable through various computer means and may be recorded in a computer-readable recording medium.

According to various embodiments, the electronic device 20 may include a stand-alone host computing system, an on-board computer system integrated with the user device 10, a mobile device, or any other hardware platform capable of providing, to the user device 10, a CAD Representation-based 3D model generation function and an editing function. For example, the electronic device 20 may include a cloud-based computing architecture suitable for servicing 3D model generation and editing executed on the user device 10. Accordingly, the electronic device 20 may include one or more servers and a database 50. For example, the electronic device 20 may include a Software as a Service (SaaS) architecture, a Platform as a Service (PaaS) architecture, an Infrastructure as a Service (IaaS) architecture, or other similar cloud-based computing architectures.

According to various embodiments, the electronic device 20 and/or the user device 10 are not limited to the illustrated example and may be configured as one device that performs respective functions.

For example, the electronic device 20 may include a configuration included in the user device 10 and may perform functions of the user device 10. When the electronic device 20 provides the functions of the user device 10, the electronic device 20 may generate a CAD Representation-based 3D model based on user input and output, through a display device (e.g., a display), editing of the generated 3D model.

According to various embodiments, the database 30 may correspond to a storage device for storing various pieces of information generated through an operation process of the electronic device 20.

According to various embodiments, the electronic device 20 may obtain user input through the user device 10 and generate a CAD Representation.

According to one embodiment, the electronic device 20 may display, via the user device 10, a first screen including a first area including a virtual design space and a second area including a user prompt. In addition, the electronic device 20 may obtain a first user input for the first area of the first screen. The first user input may be user input including at least one of a size or a position of a 3D model to be displayed in the virtual design space.

According to one embodiment, the electronic device 20 may obtain a second user input for the second area of the first screen. For example, the electronic device 20 may obtain, via the user device 10, user input for generating the 3D model.

According to one embodiment, the electronic device 20 may generate a structured command for generation of the 3D model based on the first user input and the second user input, and may obtain a CAD Representation for generation of the 3D model based on the structured command. In addition, the electronic device 20 may obtain a visualized 3D model by rendering the CAD Representation, and may display, via the user device 10, a second screen displaying the visualized 3D model in the virtual design space.

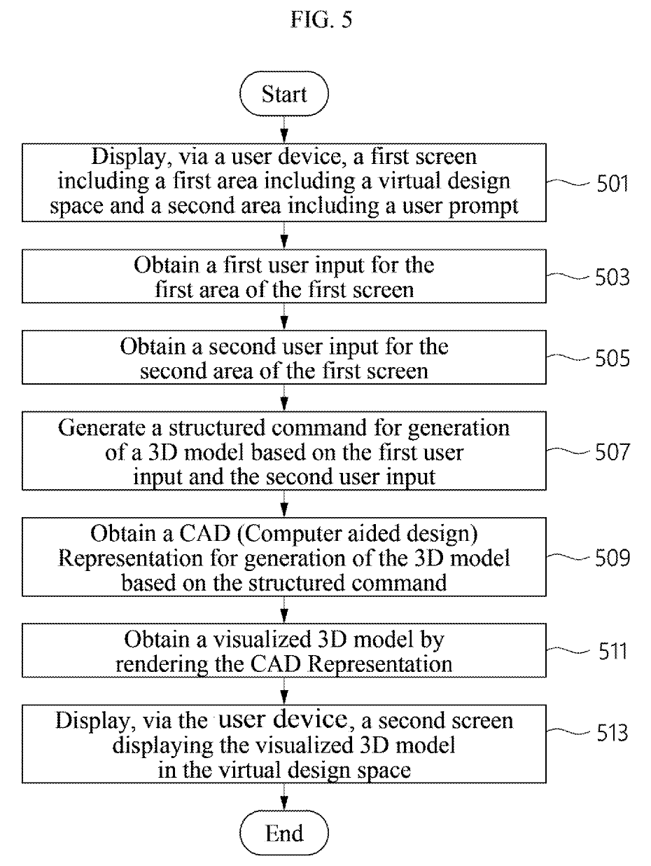

According to various embodiments, an operation in which the electronic device 20 provides a visualized 3D model based on the first user input and the second user input will be described below with reference to FIGS. 5 to 9.

According to various embodiments, the electronic device 20 may provide an editing function for a generated 3D model. According to one embodiment, the electronic device 20 may display, via the user device 10, a first screen including a first area including a first 3D model generated based on a first CAD Representation and a second area including a user prompt.

In one embodiment, the electronic device 20 may obtain a first user input for editing at least one first design element of the first 3D model via at least one of the first area and the second area. For example, the electronic device 20 may obtain, via the user device 10, user input requesting editing of the first design element including at least one of one or more parts or one or more portions constituting the first 3D model.

According to one embodiment, the electronic device 20 may obtain a second CAD Representation in which the first CAD Representation is edited based on the first user input, and may obtain a second 3D model visualized by rendering the second CAD Representation.

In addition, according to one embodiment, the electronic device 20 may display, via the user device 10, a second screen displaying the visualized second 3D model in the first area.

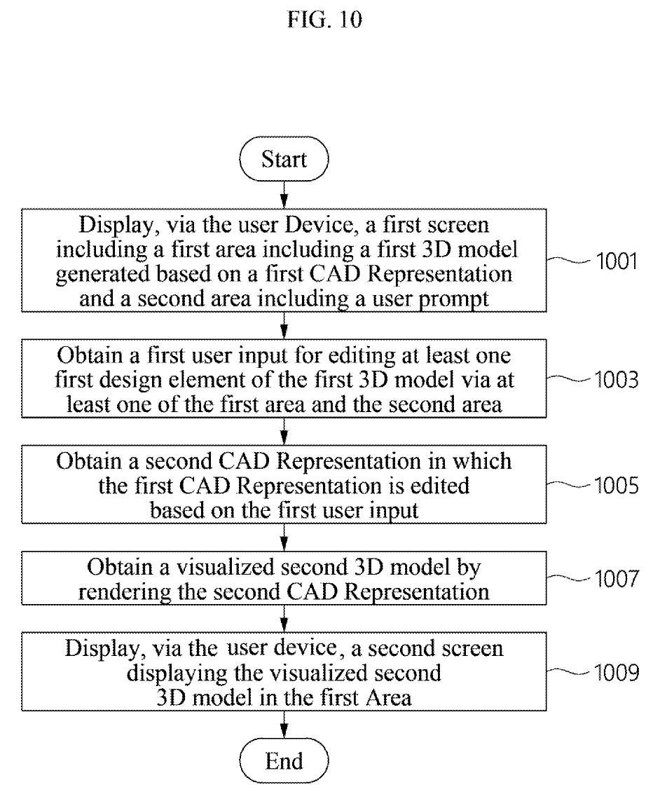

According to various embodiments, an operation in which the electronic device 20 provides an edited second 3D model based on user input for editing the first 3D model will be described below with reference to FIGS. 10 to 15.

According to various embodiments, the electronic device 20 may generate a plurality of 3D models based on user input.

According to one embodiment, the electronic device 20 may display, via the user device 10, a first screen including a first area including a first virtual design space and a second area including a user prompt.

According to one embodiment, the electronic device 20 may obtain a user input for the first screen. For example, the electronic device 20 may obtain, via the user device 10, user input for generating a plurality of 3D models.

According to one embodiment, the electronic device 20 may generate a plurality of CAD Representations based on the user input, and may obtain a plurality of visualized 3D models by rendering each of the plurality of CAD Representations.

In addition, the electronic device 20 may display the plurality of visualized 3D models via the user device 10.

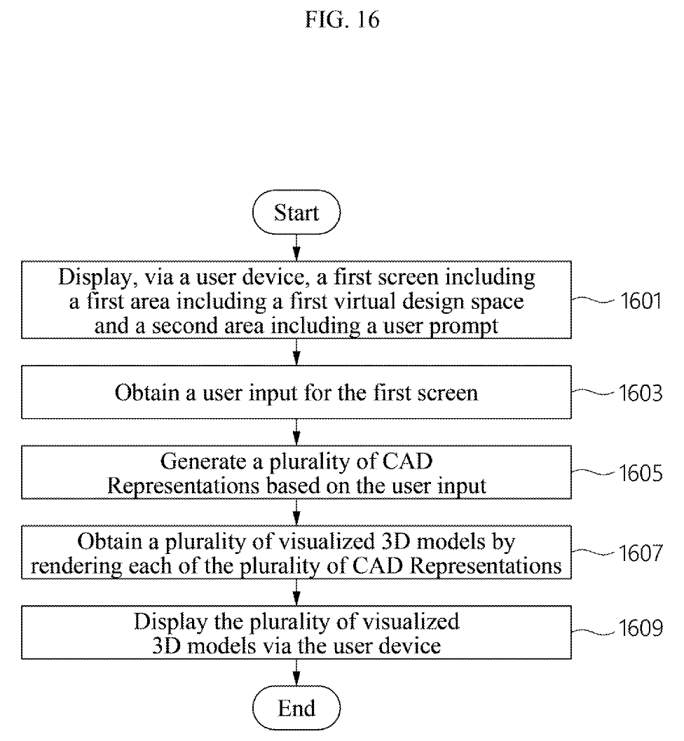

According to various embodiments, an operation in which the electronic device 20 generates a plurality of 3D models based on user input will be described below with reference to FIGS. 16 to 19.

According to various embodiments, the electronic device 20 may provide design information for a 3D model generated through the user device 10.

According to one embodiment, the electronic device 20 may display, via the user device 10, a first screen displaying a first 3D model, generated based on a first CAD Representation, in a virtual design space.

According to one embodiment, the electronic device 20 may obtain a first user input requesting design visualization information for the first 3D model, and may obtain design information for a plurality of design elements constituting the first 3D model via the first CAD Representation based on the first user input. In this case, the plurality of design elements may include at least one of one or more parts or one or more portions constituting the first 3D model.

According to one embodiment, the electronic device 20 may display, via the user device 10, a second screen including a first visual object representing design visualization information of at least some of the plurality of design elements based on the design information.

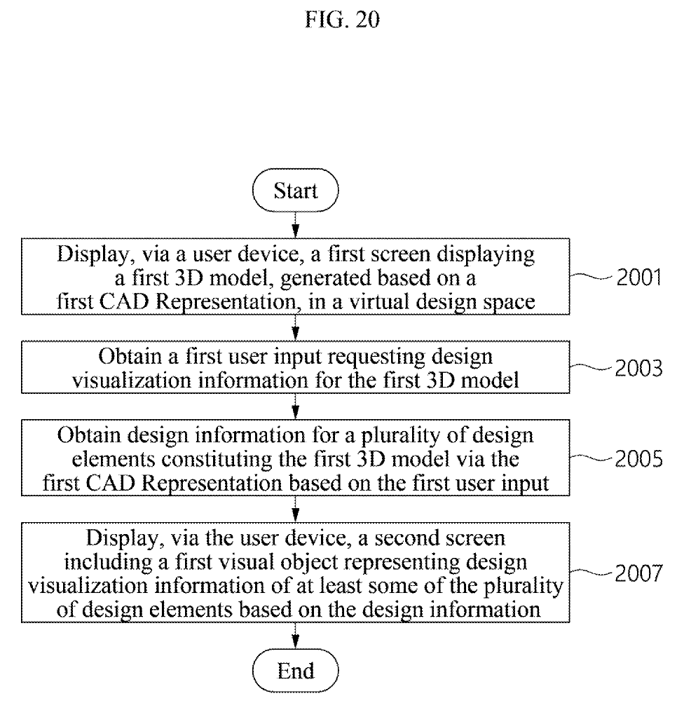

According to various embodiments, an operation in which the electronic device 20 provides design information for a 3D model will be described below with reference to FIGS. 20 to 23.

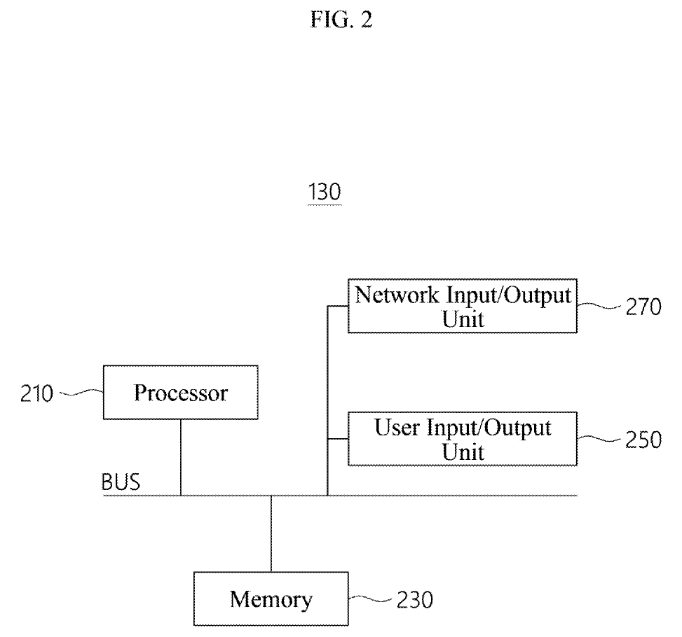

FIG. 2 is a diagram illustrating a physical configuration of an electronic device 200 according to one embodiment.

Referring to FIG. 2, the electronic device 200 (e.g., the electronic device 20 of FIG. 1) may be implemented to include a processor 210, a memory 230, a user input/output unit 250, and a network input/output unit 270. The listed components may be operatively or electrically connected to each other. The components of the electronic device 200 illustrated in FIG. 2 are merely an example, and some components may be modified, omitted, or added.

The processor 210 may include at least one processor implemented to provide at least partially different functions. The processor 210 may control overall operations of the electronic device 200 and may be electrically connected to the memory 230, the user input/output unit 250, and the network input/output unit 270 to control data flow thereamong. The processor 210 may be implemented as a CPU (Central Processing Unit) of the electronic device 200. According to one embodiment, the processor 210 may include a main processor (e.g., a central processing unit or an application processor) and/or an auxiliary processor operable independently of or together with the main processor (e.g., a graphics processing unit, a neural processing unit (NPU), an image signal processor, a sensor hub processor, or a communication processor). For example, when the electronic device 200 includes a main processor and an auxiliary processor, the auxiliary processor may be configured to consume lower power than the main processor or to be specialized for a designated function. The auxiliary processor may be implemented separately from the main processor or as a part thereof. The auxiliary processor may, for example, control at least a portion of functions or states related to at least one component of the electronic device 200, instead of the main processor while the main processor is in an inactive (e.g., sleep) state, or together with the main processor while the main processor is in an active (e.g., application execution) state. According to one embodiment, the auxiliary processor (e.g., an image signal processor or a communication processor) may be implemented as a part of another functionally related component. According to one embodiment, the auxiliary processor (e.g., a neural processing unit) may include a hardware architecture specialized for processing an artificial intelligence model. The artificial intelligence model may be generated through machine learning. Such learning may be performed, for example, in the electronic device 200 in which the artificial intelligence model is executed, or may be performed through a separate server. Learning algorithms may include, for example, supervised learning, unsupervised learning, semi-supervised learning, or reinforcement learning, but are not limited thereto. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or any combination of two or more thereof, but is not limited thereto. The artificial intelligence model may additionally or alternatively include a software architecture in addition to a hardware architecture. Meanwhile, operations of the electronic device 200 described below may be understood as operations of the processor 210.

The memory 230 may include an auxiliary storage device implemented as a non-volatile memory such as a solid state drive (SSD) or a hard disk drive (HDD) to store overall data required for the electronic device 200, and may include a main memory implemented as a volatile memory such as random access memory (RAM). In addition, the memory 230 may include a plurality of instructions for instructing operations of the processor 210 to implement functions provided by a service. In this case, the processor 210 may include a software server that executes functions provided by the service based on the plurality of instructions stored in the memory 230.

The user input/output unit 250 may include an environment for receiving user input and an environment for outputting specific information to a user. For example, the user input/output unit 250 may include an input device including an adapter such as a touch pad, a touch screen, a virtual keyboard, or a pointing device, and an output device including an adapter such as a monitor or a touch screen. In one embodiment, the user input/output unit 250 may correspond to a computing device accessed through remote access, and in this case, the electronic device 200 may operate as a server.

The network input/output unit 270 may include an environment for connecting to an external device or system through a network, and may include, for example, an adapter for communication such as a local area network (LAN), a metropolitan area network (MAN), a wide area network (WAN), or a value added network (VAN).

According to various embodiments, the electronic device 200 may include a computer system. For example, the computer system may be at least one of an embedded computer system, a system-on-chip (SoC), a single-board computer system (SBC), a computer-on-module (COM), a system-on-module (SOM), a desktop computer system, a laptop or notebook computer system, a server, a tablet computer system, or a mobile terminal. For example, the electronic device 200 may include one or more computer systems residing in a cloud including one or more cloud components.

According to various embodiments, the electronic device 200 may perform one or more operations of one or more methods described or illustrated in the present disclosure without substantial spatial or temporal limitation. In addition, the electronic device 200 may perform one or more operations of one or more methods described or illustrated in the present disclosure in real time or in a batch mode. For example, the electronic device 200 may perform one or more operations of one or more methods described or illustrated in the present disclosure at different times or at different steps.

According to various embodiments, a non-transitory computer-readable recording medium storing computer instructions for causing the electronic device 200 to perform operations described in the present disclosure may be provided. The non-transitory computer-readable recording medium or storage medium may include one or more semiconductor-based or other integrated circuits (ICs) (e.g., a field-programmable gate array (FPGA) or an application-specific integrated circuit (ASIC)), a hard disk drive (HDD), a hybrid hard drive (HHD), an optical disk, an optical disk drive (ODD), a magneto-optical disk, a magneto-optical drive, a floppy diskette, a floppy disk drive (FDD), a magnetic tape, a solid-state drive (SSD), a RAM drive, a secure digital card or drive, any other suitable computer-readable non-transitory storage medium, or any suitable combination of two or more thereof.

According to various embodiments, the computer-readable non-transitory recording medium may be volatile, non-volatile, or a combination of volatile and non-volatile, as appropriate. A machine-readable recording medium may be provided in the form of a non-transitory recording medium. Here, the term “non-transitory recording medium” means a tangible device and does not include a signal (e.g., an electromagnetic wave), and the term does not distinguish between a case in which data is semi-permanently stored in a recording medium and a case in which data is temporarily stored therein. For example, the “non-transitory recording medium” may include a buffer in which data is temporarily stored.

A method of operating an electronic device according to various embodiments disclosed herein may be provided as being included in a computer program product. The computer program product may be traded between a seller and a purchaser as a commodity. The computer program product may be distributed in the form of a machine-readable recording medium (e.g., a compact disc read only memory (CD-ROM)), or may be distributed online through an application store (e.g., Play Store™) or directly between two user devices (e.g., smartphones) (e.g., via download or upload). In the case of online distribution, at least a portion of the computer program product (e.g., a downloadable app) may be at least temporarily stored or temporarily generated in a machine-readable storage medium such as a memory of a manufacturer’s server, an application store server, or a relay server.

According to various embodiments, when the electronic device 200 described in the present disclosure provides functions of the user device 10, the electronic device 200 may include at least one display device (e.g., the user input/output unit 250) and/or an input device (e.g., the user input/output unit 250). In this case, a series of operations described in the present disclosure in which the electronic device 200 obtains user input through the user device 10 or displays a screen through the user device 10 may be understood as operations in which the electronic device 200 obtains user input through an input device or displays a screen through a display device.

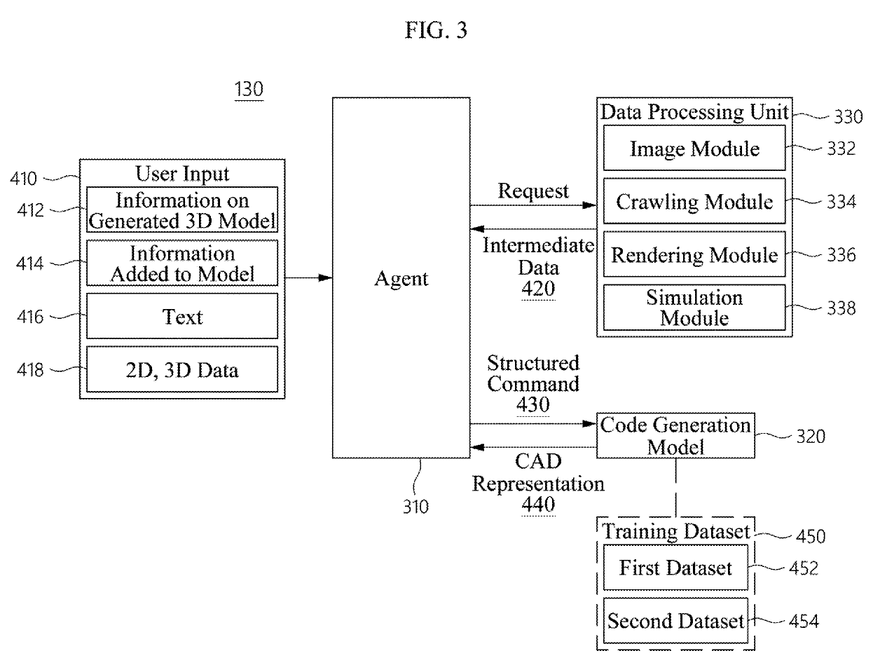

FIG. 3 is an internal functional block diagram of an electronic device 200 according to one embodiment of the present disclosure.

Hereinafter, for convenience of description, an agent 310 or each module may be described as a subject of an operation, but this may be an operation performed by at least one processor 210 included in the electronic device 200 by executing instructions stored in a memory 230. Referring to FIG. 3, the electronic device 200 may include an agent 310, a code generation model 320, and a data processing unit 330.

When an overall operation of the present disclosure is described from the perspective of an AI agent, the agent 310 may perform a role of an orchestrator that oversees an entire data processing flow. For example, the agent 310 may be implemented based on a large language model (LLM), and may interpret user input to select a specific module in the data processing unit 330 required for achieving a goal and determine an invocation order thereof. In this case, individual data processing modules such as an image module 332 and a crawling module 334 may correspond to respective “tools” used by the AI agent, and details thereof will be described below.

In one embodiment, the agent 310 may be implemented to include, by itself, one or more artificial intelligence models. For example, the agent 310 may be configured as an ensemble of a plurality of artificial intelligence models dedicated to specific subtasks, such as a natural language processing (NLP) model that analyzes natural language of user input 410, an image classification model that identifies a type of an image, and a reinforcement learning-based scheduling model that determines an invocation order of modules. In another embodiment, the agent 310 may be implemented as a single large language model (LLM) capable of performing all of such composite analysis, determination, and control functions.

The agent 310 may obtain user input 410 from a user.

According to one embodiment, the agent 310 may obtain the user input 410 through the user device 10 and/or the user input/output unit 250 of the electronic device 200. For example, the agent 310 may obtain user input (e.g., a first user input, a second user input) described with reference to FIG. 1.

As illustrated in the drawings, the user input 410 may be multimodal input including data in various forms, such as information 412 about a previously generated 3D model, added information 414 such as a sketch or an annotation added by a user to the model, natural language text 416, or 2D/3D data 418. The agent 310 may comprehensively analyze a type and content of the received user input 410 and may perform a control role of determining an overall processing flow required for 3D model generation (or editing).

In one embodiment, the agent 310 may extract a keyword from text included in the user input 410 and may identify a format of data included together. This is to identify roles and meanings of various data included in multimodal input and to select an optimal processing module. For example, the agent 310 may extract a specific product name such as “Galaxy S24” as a keyword to recognize a need to execute the crawling module 334, and may prepare execution of the image module 332 when a format of the input data is an image or a sketch. Through such an analysis process, the agent 310 may prepare basic information for determining a processing flow.

In one embodiment, when the agent 310 determines that the user input 410 is ambiguous or insufficient and it is difficult to generate a structured command, the agent 310 may perform an interactive query requesting additional information from a user. For example, when a user inputs “Make a cool chair,” the agent 310 may determine that a criterion of the expression “cool” is ambiguous, and may present, to the user, a question requesting specific information, such as “What style (e.g., modern, classic) do you want?” or “Do you have a preferred material?” Through such an interactive query, the agent 310 may clarify requirements through interaction with the user and ultimately generate a 3D model that better matches a user’s intent.

In addition, in one embodiment, the agent 310 may generate or optimize a structured command by referring to a previously stored user profile. The user profile may include a user’s past work history, frequently used design styles, preferred materials, or design specifications that must be complied with in a specific project. For example, when “preference for a minimalism style” is recorded in a profile of a specific user, even when the user simply inputs “Make a table,” the agent 310 may generate a structured command including design parameters of a minimalism style by referring to the profile. Through this, it is possible to automate generation of a customized 3D model suitable for a tendency of each user or characteristics of a project, thereby increasing efficiency and satisfaction of work.

In addition, the agent 310 may request the data processing unit 330 to perform a specific task based on an analysis result. The data processing unit 330 may include at least one processing module, and may include, for example, an image module 332 for extracting 3D information from an image, a crawling module 334 for searching for information from an external source, a rendering module 336 for visualizing a CAD Representation as a 3D model, or a simulation module 338 for generating comprehensive evaluation (e.g., CAE-based evaluation, BOM-based evaluation) information of a generated CAD model. After performing the requested task, the data processing unit 330 may transmit intermediate data 420, which is a result thereof, to the agent 310.

The intermediate data 420 may be at least one of geometric shape information obtained from the image module 332, text-based specification information obtained from the crawling module 334, or semantic information extracted from text of the user input 410. In one embodiment, the intermediate data 420 may be managed in the form of a structured data object. For example, such a data object may include, in addition to raw data generated from a processing module, metadata indicating a processing priority of the data or a relationship with other data. By managing the intermediate data in a structured manner, the agent 310 may efficiently integrate heterogeneous data from various sources and may provide clear grounds for generating a final structured command.

In one embodiment, the agent 310 may analyze the user input 410 to determine whether 3D information needs to be obtained, and when it is determined that 3D information needs to be obtained, the agent 310 may selectively execute the image module 332. This is to prevent performing unnecessary computation for all requests and to efficiently use system resources. For example, when a user requests conceptual generation such as “Make a metal cylinder,” the agent 310 may determine that it is unnecessary to obtain 3D information and may not execute the image module 332. In contrast, for a request that refers to a specific shape, the agent 310 executes the image module 332 to obtain necessary 3D information.

According to one embodiment, the image module 332 may extract geometric and structural features necessary for generation of a three-dimensional model from two-dimensional visual data. For example, the image module 332 may analyze outlines of a sketch, proportions of major parts, depth perception, and the like, and may convert the same into quantified 3D information. The image module 332 may reply the extracted 3D information to the agent 310 as intermediate data. Finally, the agent 310 may generate a structured command 430 by integrating a user’s initial text command and the 3D information received from the image module, and may transmit the structured command 430 to the code generation model 320.

In one embodiment, the agent 310 may analyze an intent of a generation request contained in the user input 410, and when the intent is to generate a 3D model while maintaining or transforming a geometric shape of specific data input together, the agent 310 may determine that the 3D information needs to be obtained. Here, “maintaining a shape” may include a case in which a sketch or image provided by a user is restored as a 3D model as it is. In addition, “transforming a shape” may include a case in which a new 3D model is generated by modifying a specific parameter based on geometric features of input data, such as “Make it similar to this chair image, but increase the leg length by 10 cm.” Through such determination, the agent 310 may fulfill a user’s complex and specific requirements.

According to various embodiments, the user input 410 may be user input having various intents. For example, the user input may include user input for generating a 3D model, user input for editing a 3D model, user input for generating a plurality of 3D models, or user input for requesting design information. Operations of the agent 310 that provides a service according to specific user input 410 will be described below.

In addition, according to one embodiment, the agent 310 may generate a structured command 430 in a format that the code generation model 320 can understand by integrating initial user input 410 and intermediate data 420 received from the data processing unit 330.

According to one embodiment, the structured command 430 may be transmitted to the code generation model 320. The code generation model 320 may be an artificial intelligence model pre-trained based on a training data set 450. The training data set 450 may include a first data set 452 including first programming code and annotation information, and a second data set 454 including second programming code corresponding to the first programming code. Here, the annotation information may include an execution purpose or an intent of code.

According to various embodiments, the code generation model 320 may receive, as input, the structured command 430 generated from the agent 310. The code generation model 320 may interpret the received structured command 430 and may generate and output a CAD Representation 440 as a final result corresponding thereto. In this case, the CAD Representation 440 is not limited to a specific format. In one embodiment, the CAD Representation 440 may be a text-based CAD code comprising functions and parameters mathematically defining NURBS surfaces and the like. In another embodiment, the CAD Representation 440 may be a data structure including design information defining components of a three-dimensional model and relationships therebetween, and may include, for example, a data structure in which GFL (Geometric Figure Library) objects are configured in a tree form. More specifically, a case of generating a chair model may be taken as an example. In this case, a top-level object (Root Object) representing an entire “chair” exists, and component objects such as “seat,” “backrest,” and “leg” may be connected as child nodes (Child Nodes) thereunder, and thus a hierarchical data structure may be generated as the CAD Representation. In this case, each component object may have shape information defined in GFL and unique parameters (dimensions, materials, and the like). As such, the present disclosure may increase flexibility by generating CAD Representations in various forms.

For this, the code generation model 320 may be pre-trained based on the training data set 450. The training data set 450 may include the first data set 452 and the second data set 454.

The first data set 452 may constitute training input of the model and may include first programming code and annotation information. Here, the first programming code may correspond to high-level source code representing a design process of a 3D model (e.g., modeling history of CAD software), and the annotation information may correspond to CoT (Chain-of-Thought) data describing a design intent or determination grounds for each step of the first programming code. That is, the first programming code may be modeling history recorded while a user generates or edits a 3D model in CAD software, and the annotation information may include a design intent or determination grounds therefor. For example, when the first programming code corresponds to code for “create a cylinder, add a smaller cylinder on an end, and round an upper edge,” corresponding annotation information may include text describing a design intent of each step, such as “create a body of a water bottle,” “create a neck portion,” and “improve usability of a portion that contacts a user’s lips.”

Here, the annotation information may be generated in various ways. In one embodiment, the annotation information may be automatically generated by a separate large language model (LLM) trained to analyze the first programming code and infer an intent thereof. This may be used to efficiently construct training data from a large amount of modeling history.

In another embodiment, the annotation information may be directly input as text by a user who is a design expert. By combining an automatic generation scheme and a manual input scheme in this manner, it is possible to secure both quantity and quality of training data and to maximize performance of the code generation model 320 by reflecting refined knowledge of an expert in data as needed.

According to one embodiment, the second data set 454 may constitute data corresponding to a “correct answer” in model training and may include second programming code. The second programming code may correspond to low-level target code (e.g., GFL code) capable of representing NURBS (Non-Uniform Rational B-Spline) surfaces, as a result finally implemented by a design process of the first programming code. Specifically, the second programming code may be provided in the form of a library of a general-purpose programming language and may include at least one function and parameter for mathematically defining a shape expressed by NURBS surfaces. For example, the second programming code corresponding to the first programming code described above as “create a cylinder, add a neck, and process an edge” may have the form of GFL code. That is, the second programming code may be configured with a series of function calls and parameter values describing a precise shape of a 3D model mathematically. As such, the code generation model 320 may be trained to generate such “correct answer” code finally by referring to a process and an intent of the first data set 452.

In one embodiment, the code generation model 320 may generate a CAD Representation 440 as a final result based on the received structured command 430 and may transmit the CAD Representation 440 to the agent 310. The agent 310 may control subsequent processing, such as by sending the CAD Representation 440 to the rendering module 336 to visualize the CAD Representation 440 or sending the CAD Representation 440 to the simulation module 338 to generate additional information.

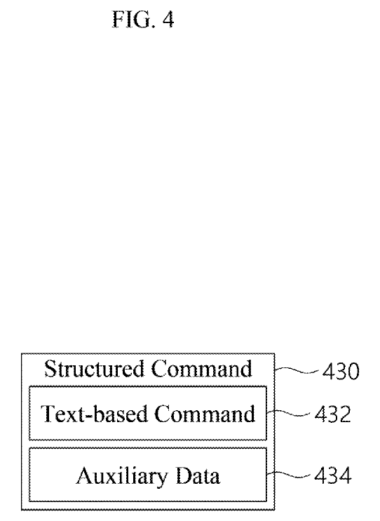

FIG. 4 is a block diagram of a structured command according to one embodiment of the present disclosure.

Referring to FIG. 4, the structured command may include a text-based command 432 and auxiliary data 434. This may be a final information packet processed by the AI agent 310 by integrating complex requirements of a user and various intermediate data so that the code generation model 320 can clearly understand and execute the final information packet.

In one embodiment, the structured command may follow a data structure (schema) defined by rules or templates of a preset database. Such rules or templates define required fields that must be included in the structured command 430, data formats of respective fields, and default values of parameters, so that the structured command 430 can be consistently processed by the code generation model 320. The AI agent 310 analyzes user input and fills values of respective fields according to the predefined data structure to complete the final structured command 430.

In addition, when user input is insufficient or ambiguous such that all required fields defined by the rules or templates cannot be filled, the agent 310 may automatically fill the fields with a preset default value or a most probable value to generate the structured command 430. Through this, even when a user does not provide all information in detail, the system may generate a complete form of a command to ensure stable operation.

In one embodiment, the structured command 430 may be a prompt provided to an artificial intelligence model for generating a CAD Representation, and may include at least one of a target shape of a 3D model, numerical constraint conditions, part-wise relationship information, or material information. This may be a result obtained by translating various requirements of a user into language that the code generation model 320 can clearly understand by the agent 310.

For example, it is assumed that a user inputs, “Make it similar to a phone of Company A, but change only a back surface material to matte black.” In this case, the agent 310 may first obtain, as intermediate data, accurate dimensions (width, height, thickness) of the model and arrangement information of components (e.g., a camera) from an external source based on a keyword “a phone of Company A.” Thereafter, the agent 310 may integrate the obtained intermediate data and an additional request of the user (“back surface material: matte black”) to generate the structured command 430 including the following information.

According to various embodiments, the agent 310 may generate a structured command 430 based on various user inputs such as user input for generating a 3D model, user input for editing a 3D model, or user input for generating a plurality of 3D models, and may generate a CAD Representation based on the structured command 430. Operations of the agent 310 for generating a structured command according to specific user input will be described below.

FIG. 5 is a flowchart illustrating operations in which an electronic device provides a 3D model based on user input according to various embodiments.

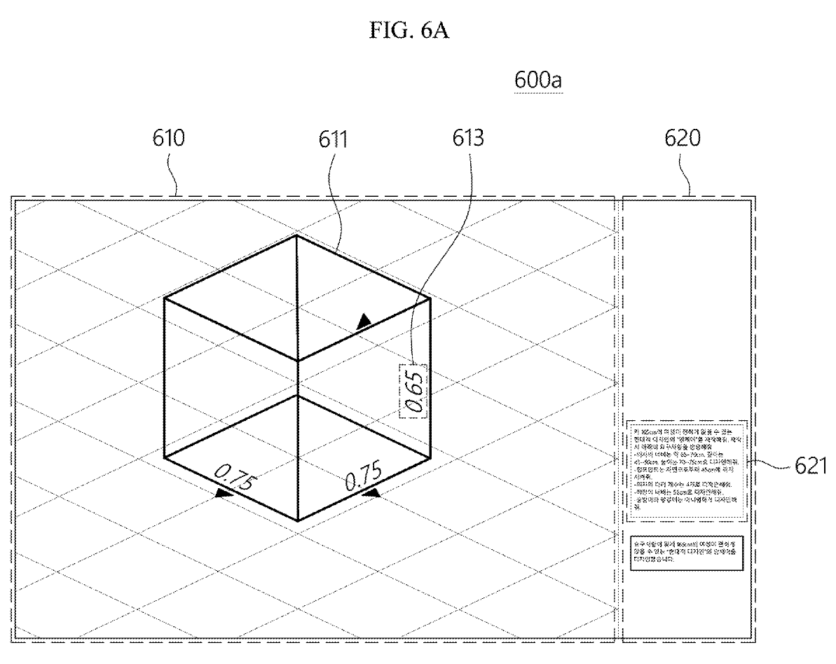

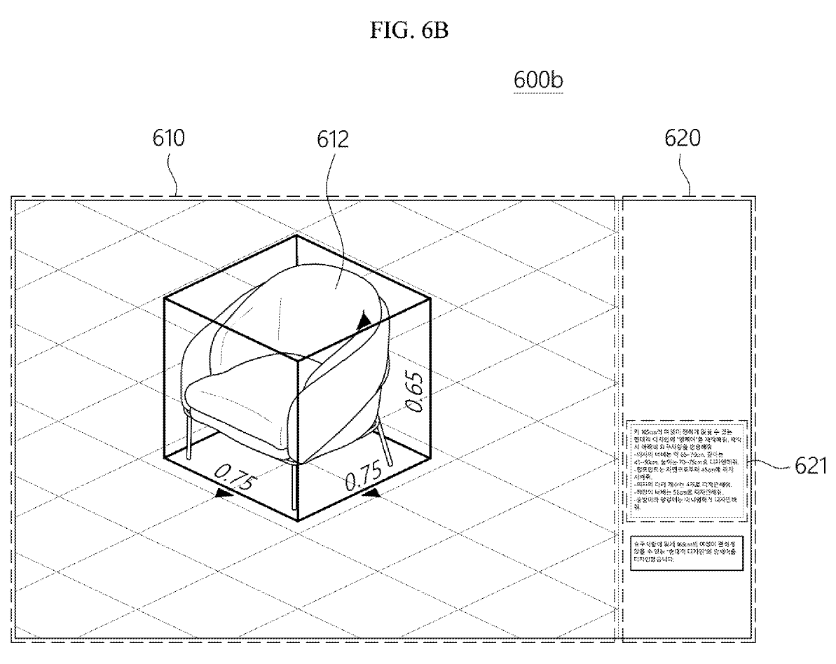

FIG. 6A is a diagram illustrating a user interface for obtaining user input according to various embodiments.

FIG. 6B is a diagram illustrating a user interface for displaying a 3D model generated according to user input according to various embodiments.

Each of the operations described below may be performed in combination with one another. In addition, among the operations described below, operations performed by the electronic device 200 (e.g., the electronic device 20 of FIG. 1 and the electronic device 200 of FIG. 2) may be understood as operations performed by a processor 210 (e.g., the processor 210 of FIG. 3) of the electronic device 200.

Further, “information” described below may be interpreted as meaning “data” or “signal,” and “data” may be understood as a concept including both analog data and digital data.

According to various embodiments, the operations illustrated in FIG. 5 are not limited to the illustrated order and may be performed in various orders. In addition, according to various embodiments, more operations than those illustrated in FIG. 5 may be performed, or fewer operations including at least one operation may be performed.

Referring to FIG. 5, in operation 501, the electronic device 200 may display, via a user device (e.g., the user device 10 of FIG. 1), a first screen including a first area including a virtual design space and a second area including a user prompt.

According to various embodiments, the electronic device 200 may display, via the user device 10, a screen including a plurality of input spaces. For example, the electronic device 200 may display, through a graphical user interface (GUI), the first screen including the virtual design space and a user prompt input space.

In one embodiment, the virtual design space may be a space in which a user inputs visual and intuitive data such as a sketch, a 2D image, or a 3D model. In addition, the virtual design space may be a virtual space in which a 3D model generated based on user input is displayed. In one embodiment, the user prompt may be a space in which a user inputs specific requirements or constraint conditions such as natural language text, numerical values, materials, or colors.

Referring to FIG. 6A, the user device 10 may display a first screen 600a under control of the electronic device 200. According to one embodiment, the first screen 600a may include a first area 610 including a virtual design space and a second area 620 including a user prompt.

According to various embodiments, in operation 503, the electronic device 200 may obtain a first user input for the first area of the first screen. For example, the electronic device 200 may obtain, via the user device 10, a first user input 611 for the first area 610 of the first screen 600a.

In one embodiment, the first user input 611 may include at least one of a size or a position of a 3D model to be displayed in the virtual design space. For example, the user device 10 may obtain, from a user, the first user input 611 indicating a size and/or a position of a 3D model to be generated, and may transmit the first user input 611 to the electronic device 20.

In one embodiment, the first user input 611 may be a user input for the virtual design space and may include at least one of a bounding box input, a masking input for a specific region, or a sketch input. For example, a size of a bounding box of the first user input 611 may indicate a size of the 3D model to be generated, and a position of the bounding box may indicate a position of the 3D model in the virtual design space.

In one embodiment, the user device 10 may display related information in response to the first user input 611 on the first screen 600a. For example, the electronic device 200 may display, via the user device 10, a visual object 613 representing size information and position information of the 3D model to be generated in the first area 610 based on the first user input 611.

According to various embodiments, without being limited to the example illustrated in FIG. 6A, the user device 10 may obtain various types of the first user input 611 (e.g., a sketch, a masking input, text, or an image), and may display various visual objects 613 (e.g., size information or position information) representing information of the first user input 611.

According to various embodiments, in operation 505, the electronic device 200 may obtain a second user input for the second area of the first screen. For example, the electronic device 200 may obtain, via the user device 10, a second user input 621 for the second area 620 of the first screen 600a. In one embodiment, the second user input 621 may include a user input for generating the 3D model.

In one embodiment, the second user input 621 may include at least one of a text input, a 2D image input, a sketch input, or a 3D data input for the 3D model to be generated. The electronic device 200 may control a display of the user device 10 to provide various user interfaces for obtaining the second user input 621, such as a user interface for text input, an image file upload interface (2D images or 3D images), or a sketch input interface. The electronic device 200 may obtain the second user input 621 through the user interface displayed in the second area 620.

In one embodiment, the electronic device 200 may comprehensively obtain a plurality of inputs (multimodal inputs) through the first area 610 and the second area 620 to more accurately identify user intent.

According to various embodiments, in operation 507, the electronic device 200 may generate a structured command for generation of a 3D model based on the first user input and the second user input. For example, the electronic device 200 may generate the structured command (e.g., the structured command 430 of FIG. 4) by using both the first user input 611 obtained through the virtual design space and the second user input 621 obtained through the user prompt.

In one embodiment, the electronic device 200 may generate the structured command by using 3D information as necessary. For example, the electronic device 200 may determine, based on at least one of the first user input 611 or the second user input 621, that acquisition of 3D information is required. When it is determined that acquisition of 3D information is required, the electronic device 200 may extract 3D information for at least one of the first user input 611 or the second user input 621 through an image module (e.g., the image module 332 of FIG. 3), and may generate the structured command for generation of the 3D model by using the extracted information.

According to various embodiments, in operation 509, the electronic device 200 may obtain a CAD (Computer aided design) Representation for generation of the 3D model based on the structured command. For example, the electronic device 200 may generate the CAD Representation (e.g., the CAD Representation 440 of FIG. 3) by interpreting the structured command.

According to various embodiments, in operation 511, the electronic device 200 may obtain a visualized 3D model by rendering the CAD Representation. For example, the electronic device 200 may obtain the visualized 3D model through a rendering module 336 described with reference to FIG. 3.

According to various embodiments, in operation 513, the electronic device 200 may display, via the user device, a second screen displaying the visualized 3D model in the virtual design space. For example, the electronic device 200 may control the user device 10 to display the visualized 3D model.

Referring to FIG. 6B, a second screen 600b displaying the generated 3D model 612 is illustrated. The user device 10 may display, under control of the electronic device 200, the generated 3D model 612 in the virtual design space included in the first area 610. That is, the generated 3D model 612 may be displayed in the same virtual design space in which the first user input 611 was obtained. Accordingly, as the 3D model 612 generated based on the first user input 611 is displayed in the area in which the first user input 611 was obtained, an association between the user input and the generated 3D model may be emphasized.

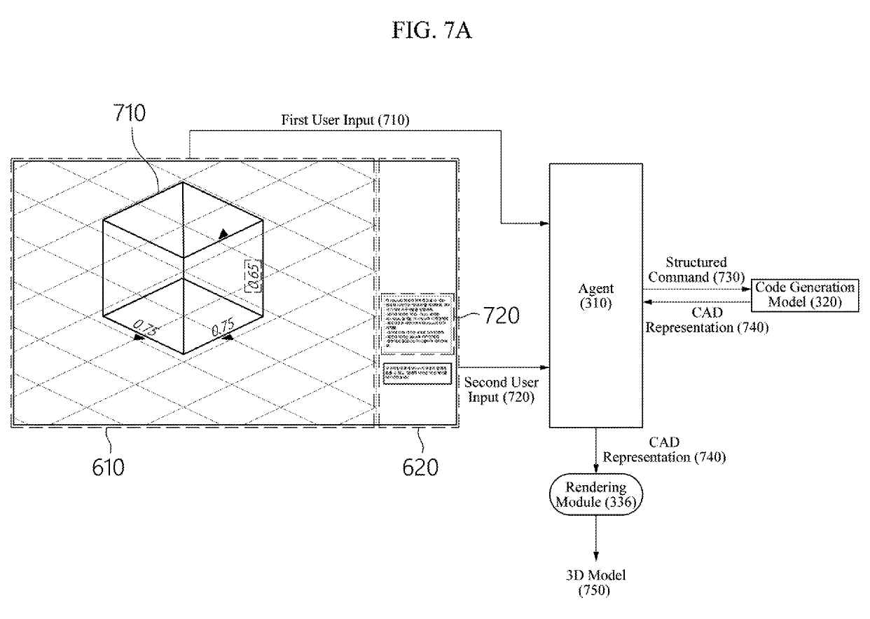

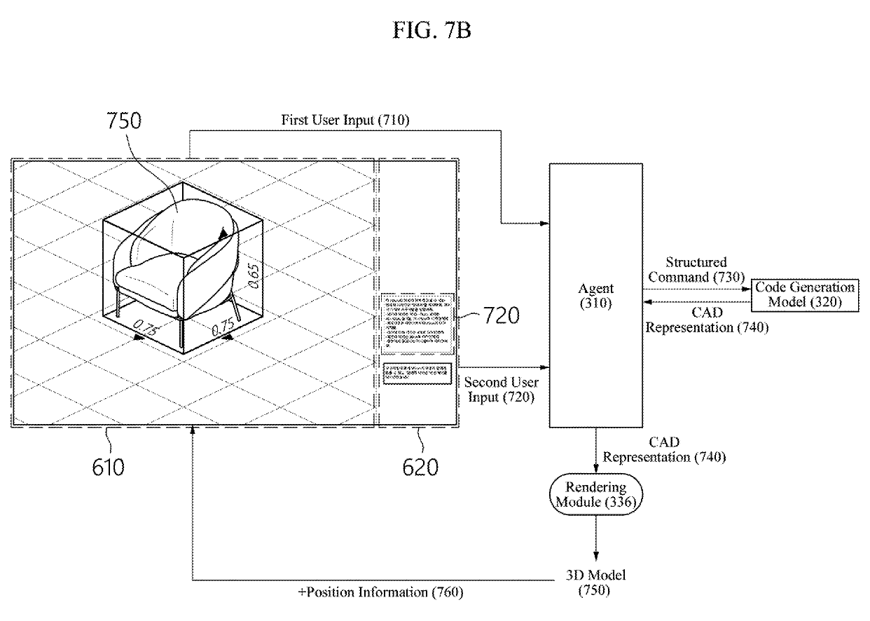

FIG. 7A is a diagram for explaining that an electronic device generates a 3D model based on user input according to various embodiments.

FIG. 7B is a diagram for explaining that an electronic device displays a 3D model based on position information according to various embodiments.

Referring to FIG. 7A, a flow in which the electronic device 200 obtains a first user input 710 (e.g., the first user input 611 of FIG. 6A) and a second user input 720 (e.g., the second user input 621 of FIG. 6A) and generates a 3D model is illustrated. Hereinafter, descriptions that are redundant with or similar to those of FIG. 5, FIG. 6A, and FIG. 6B may be omitted.

According to various embodiments, the electronic device 200 may display, via the user device 10, a first screen. The first screen may include a first area 610 and a second area 620. The first area 610 may include a virtual design space, and the second area 620 may include a user prompt.

According to one embodiment, the electronic device 200 may obtain, via the user device 10, a first user input 710 for the first area 610 and a second user input 720 for the second area 620.

According to one embodiment, the first user input 710 may include at least one of a size or a position of a 3D model to be displayed in the virtual design space. According to one embodiment, the electronic device 200 may obtain coordinate information based on the first user input 710. For example, the electronic device 200 may obtain the coordinate information by identifying the first user input 710 for the first area 610. For example, when the first user input 710 for the first area 610 is a bounding box input, the electronic device 200 may identify a start point and an end point of the user input and obtain coordinate information (e.g., a position of a mouse cursor, a touch input point, etc.). According to one embodiment, the electronic device 200 may extract, based on the coordinate information, size information of the 3D model and position information indicating a position in the virtual design space at which the 3D model is to be displayed.

According to various embodiments, the electronic device 200 may obtain the size information and/or the position information based on a relationship between the first user input 710 and the second user input 720. For example, the electronic device 200 may determine the position information and/or the size information by analyzing a linguistic context and/or a visual context included in the first user input 710 and/or the second user input 720. For example, when a user input points to a tabletop of an existing rendered table model and includes “Create a cup here,” the electronic device 200 may identify a position corresponding to “on the tabletop” and determine a relative size of a “cup” at coordinates corresponding to the position. That is, the electronic device 200 may determine the size information and/or the position information by identifying, based on the user input, a relationship between objects and/or a user’s design intent.

According to various embodiments, the electronic device 200 may generate a structured command 730 based on the first user input 710 and the second user input 720 through the agent 310. According to one embodiment, the structured command 730 may be a prompt provided to an artificial intelligence model to generate a CAD Representation 740. The structured command 730 may include at least one of natural language text instructing a generation or an editing operation of the 3D model, a shape of the 3D model, a target shape of the 3D model, numerical constraint conditions, part-wise relationship information, or material information. The structured command 730 may be a result of translating, by the agent 310, various user requirements (e.g., the first user input 710 and the second user input 720) into a language that the code generation model 320 can clearly understand.

According to one embodiment, the first user input 710 may include a sketch input for the virtual design space. In this case, the electronic device 200 may generate a 3D model using only the first user input 710. For example, the electronic device 200 may determine whether the first user input 710 is a sketch input for the virtual design space. When the sketch input for the virtual design space is identified, the electronic device 200 may generate the structured command 730 based on the sketch input.

For example, the agent 310 may identify that a sketch input for the virtual design space of the first area 610 is obtained as the first user input 710. In this case, the agent 310 may generate 3D information by extracting, through the image module 332, features for generation of a 3D model based on the sketch input. The image module 332 may provide the 3D information to the agent 310, and the agent 310 may generate the structured command 730 based on the 3D information.

According to one embodiment, the electronic device 200 may generate the CAD Representation 740 based on the structured command 730. For example, the code generation model 320 may receive the structured command 730 as an input. The code generation model 320 may interpret the received structured command 730 and generate and output the CAD Representation 740 as a final result corresponding thereto. According to one embodiment, the code generation model 320 may be an artificial intelligence model trained to output a text-based sequential code comprising functions or parameters defining CAD components based on the structured command 730.

According to various embodiments, the electronic device 200 may generate a visualized 3D model 750 based on the CAD Representation 740. For example, the agent 310 may obtain the CAD Representation 740 from the code generation model 320 and transmit the CAD Representation 740 to the rendering module 336. According to one embodiment, the rendering module 336 may receive the CAD Representation 740 as an input, render the CAD Representation 740, and output the visualized 3D model 750. The rendering may refer to a process of converting the CAD Representation having a mathematical and parametric data structure into a realistic 3D graphic image that a user can intuitively recognize.

According to various embodiments, the rendering module 336 may render the CAD Representation 740 that follows predefined syntax of a GFL (Geometric Figure Library) code library, thereby generating the visualized 3D model 750. According to one embodiment, the electronic device 200 may display, via the user device 10, the 3D model 750.

According to one embodiment, the rendering module 336 may interpret geometric information (e.g., points, lines, curves, surfaces), topology information (e.g., connection and assembly relationships between parts), and appearance properties (e.g., materials, colors, textures) defined in the CAD Representation 740, and may generate the visualized 3D model 750 by calculating pixel values to be displayed on a two-dimensional screen through viewing transformation and projection transformation with settings of a virtual light source, a camera position, a viewpoint, and the like.

Referring to FIG. 7B, the electronic device 200 may display the 3D model 750 in the first area 610 by using position information 760. For example, the electronic device 200 may extract the position information 760 based on coordinate information obtained based on the first user input 710. The electronic device 200 may determine a position in the virtual design space at which the generated 3D model 750 is to be displayed based on the position information 760, and may display the 3D model in the virtual design space according to the determined position.

According to one embodiment, the electronic device 200 may display, via the user device 10, a second screen (e.g., the second screen 600b of FIG. 6B) displaying, in the virtual design space, the 3D model 750 generated based on the CAD Representation 740 according to the determined position.

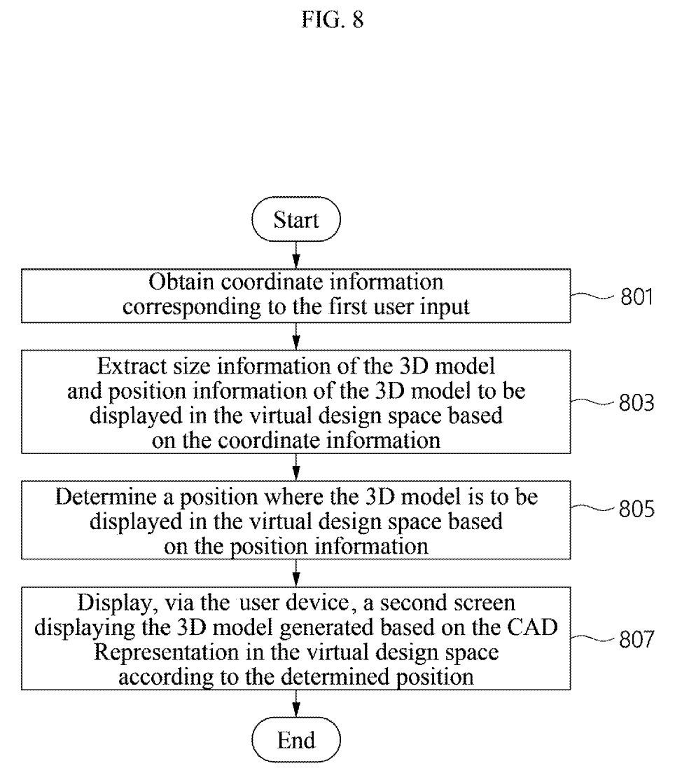

FIG. 8 is a flowchart illustrating an operation in which an electronic device displays a 3D model based on position information according to various embodiments.

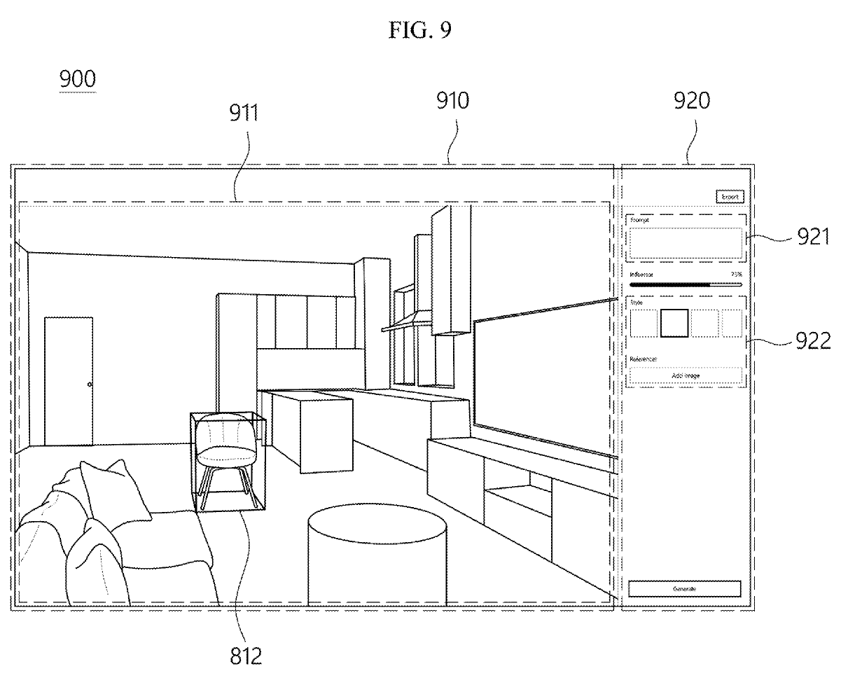

FIG. 9 is a diagram illustrating a user interface for displaying a 3D model in a virtual design space according to various embodiments.

Each of the operations described below may be performed in combination with each other. In addition, among the operations described below, an operation performed by the electronic device 200 (e.g., the electronic device 20 of FIG. 1 and/or the electronic device 200 of FIG. 2) may refer to an operation performed by the processor 210 (e.g., the processor 210 of FIG. 2) of the electronic device 200.

In addition, “information” described below may be interpreted as “data” or “signal,” and “data” may be understood as a concept including both analog data and digital data.

According to various embodiments, the operations illustrated in FIG. 8 are not limited to the illustrated order and may be performed in various orders. In addition, according to various embodiments, more operations than those illustrated in FIG. 8 may be performed, or fewer operations including at least one operation may be performed.

Referring to FIG. 8, in operation 801, the electronic device 200 may obtain coordinate information corresponding to the first user input. For example, the electronic device 200 may obtain coordinate information (e.g., the coordinate information described with reference to FIG. 7) based on a first user input (e.g., the first user input 710 of FIG. 7A). For example, the electronic device 200 may obtain the coordinate information by identifying the first user input 710 for the first area 610. For example, the electronic device 200 may obtain coordinate information for the first user input 710 using a position of a mouse cursor, a touch input point, and the like by using the first user input 710 for the first area 610.

According to various embodiments, in operation 803, the electronic device 200 may extract size information of the 3D model and position information of the 3D model to be displayed in the virtual design space based on the coordinate information. For example, the electronic device 200 may obtain coordinate information based on the first user input 710 and may identify an area determined according to the coordinate information as the size information of the 3D model. In addition, the electronic device 200 may identify a value of the coordinate information in the virtual design space as the position information of the 3D model.

According to various embodiments, in operation 805, the electronic device 200 may determine a position where the 3D model is to be displayed in the virtual design space based on the position information.

According to various embodiments, in operation 807, the electronic device 200 may display, via the user Device, a second screen displaying the 3D model generated based on the CAD Representation in the virtual design space according to the determined position.

Referring to FIG. 9, a user interface for displaying a 3D model in a virtual design space is illustrated. The user interface may include a first area 910 (e.g., the first area 610 of FIG. 6A) and a second area 920 (e.g., the second area 620 of FIG. 6A).

Referring to FIG. 9, the electronic device 200 may display, via the user device 10, a second screen 900 displaying a 3D model 912 in a virtual design space 911. For example, the electronic device 200 may display, in the first area 910, the second screen 900 including the virtual design space 911.

According to one embodiment, the virtual design space 911 may be configured in various ways. For example, as illustrated with reference to FIG. 9, the virtual design space 911 may be set as a pre-set image 911. Accordingly, a user may place and evaluate the 3D model in a context similar to a real environment rather than in a merely abstract virtual space. For example, the user may upload a photo of the user’s room, a particular interior design image, or a desired landscape photo and designate the uploaded image as a background of the virtual design space 911.

According to one embodiment, the electronic device 200 may display, via the user device 10, the second screen 900 displaying, in the virtual design space 911, the 3D model 912 generated based on the CAD Representation according to the determined position. For example, the electronic device 200 may determine a position of the 3D model 912 in the virtual design space 911 based on the position information and may display the 3D model 912. That is, the electronic device 200 may place the 3D model 912 at a specific position of the virtual design space 911, which is a 3D space reconstructed from a background image set by the user. Accordingly, the user may have an experience similar to augmented reality, such as placing the rendered 3D model 912 on the background image. This may enable a comprehensive design review in consideration of an actual application environment beyond mere modeling, thereby improving user design satisfaction and accuracy of decision-making.

According to various embodiments, the second area 920 may include various user input interfaces in addition to a user prompt 921. For example, the second area 920 may include a user prompt 921 through which a user inputs, via text and/or file upload, a description of a desired 3D model. For example, the electronic device 200 may obtain, via the user device 10, a second user input (e.g., the second user input 720 of FIG. 7) for the user prompt 921. For example, through the user prompt 921, the electronic device 200 may receive, as a text input, a composite command including a type of an object to be generated (e.g., a chair), a material (e.g., wood), and an overall design concept (e.g., classic), such as “a classic chair made of wood.”

According to various embodiments, the second area 920 may include a style selection area 922. The style selection area 922 may provide pre-defined options (e.g., Classic, Modern, Antique) such that a user can easily specify a particular design style as an auxiliary means for text input or independently. In one embodiment, when a user inputs “classic” in the user prompt 921, the system may analyze the input and automatically activate or recommend a “Classic” item among the style options 922, thereby enabling an intelligent interaction.

FIG. 10 is a flowchart illustrating an operation in which an electronic device provides an edited 3D model based on a user input according to various embodiments.

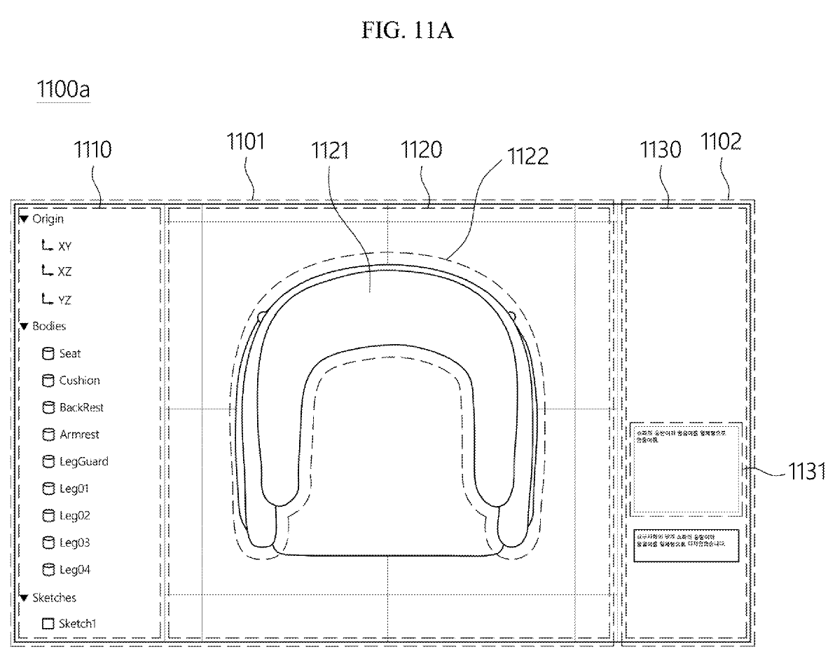

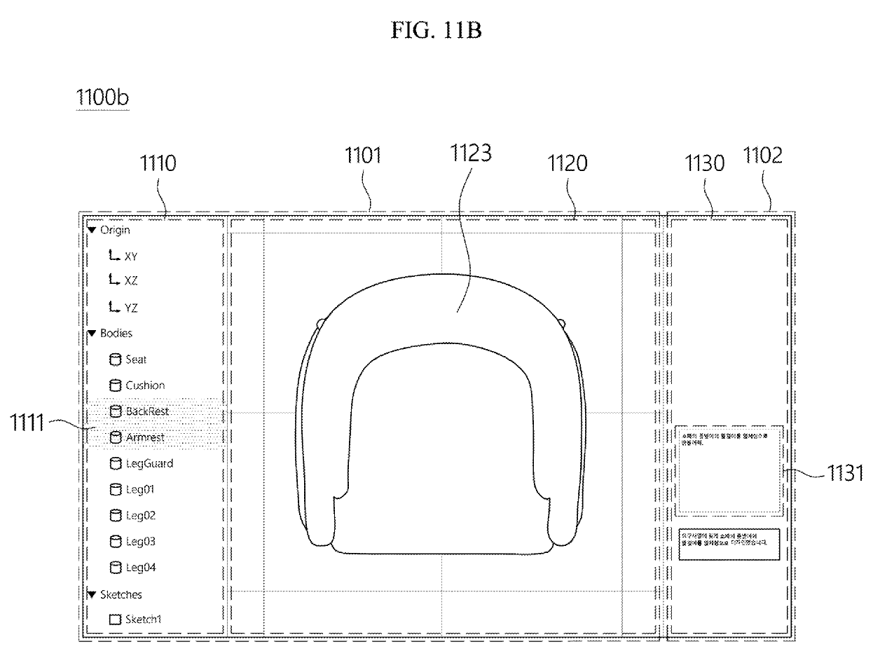

FIG. 11A is a diagram illustrating a user interface for obtaining a user input for editing a 3D model according to various embodiments.

FIG. 11B is a diagram illustrating a user interface for displaying an edited 3D model according to various embodiments.

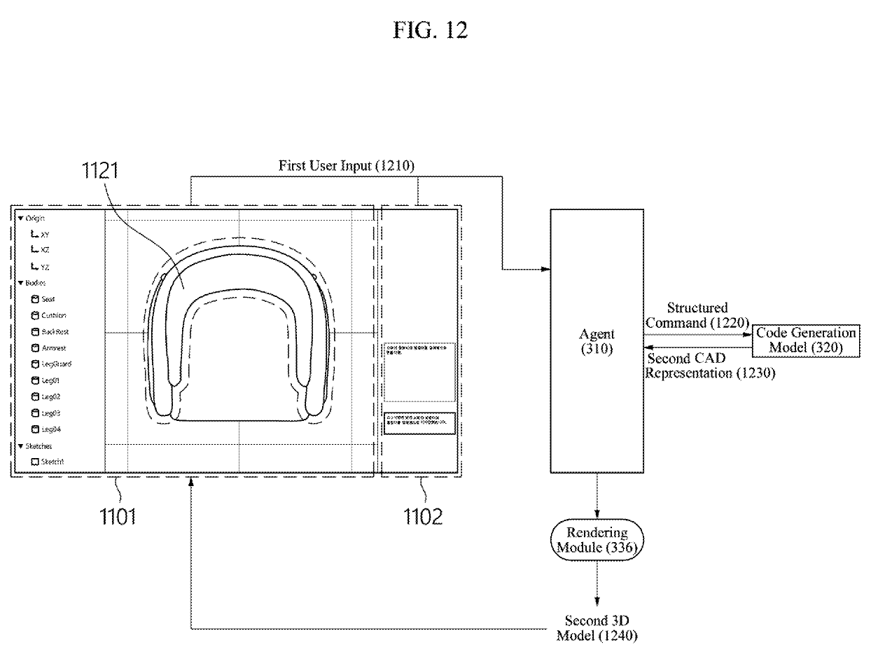

FIG. 12 is a diagram for describing that an electronic device edits a 3D model based on a user input according to various embodiments.

Each of the operations described below may be performed in combination with each other. In addition, among the operations described below, an operation performed by the electronic device 200 (e.g., the electronic device 20 of FIG. 1 and/or the electronic device 200 of FIG. 2) may refer to an operation performed by the processor 210 (e.g., the processor 210 of FIG. 2) of the electronic device 200.

In addition, “information” described below may be interpreted as “data” or “signal,” and “data” may be understood as a concept including both analog data and digital data.

According to various embodiments, the operations illustrated in FIG. 10 are not limited to the illustrated order and may be performed in various orders. In addition, according to various embodiments, more operations than those illustrated in FIG. 10 may be performed, or fewer operations including at least one operation may be performed.

Referring to FIG. 10, in operation 1001, the electronic device 200 may display, via the user Device, a first screen including a first area including a first 3D model generated based on a first CAD Representation and a second area including a user prompt. Referring to FIG. 11A, in the first area 1101 of the first screen 1100a, that is, in a virtual design space 1120, a first 3D model 1121 visually rendered based on the first CAD Representation, which is a mathematical data structure, is displayed. At the same time, in the second area 1102, a user prompt window 1130 in which a user can input a text-based command is provided together, thereby providing a work environment in which the user can organically link visual editing and linguistic editing.

According to one embodiment, the electronic device 200 may display, via the user device 10, a pre-generated first 3D model. Referring to FIG. 11A, the first screen 1100a displaying the first 3D model 1121 is illustrated. In this case, the first 3D model 1121 may be generated based on the first CAD Representation.

According to one embodiment, the first screen 1100a may include a first area 1101 (e.g., the first area 610 of FIG. 6A) including a virtual design space 1120 (e.g., the virtual design space of FIG. 6A) and a second area 1102 (e.g., the second area 620 of FIG. 6A) including a user prompt 1130.

According to one embodiment, while displaying, via the user device 10, the first screen 1100a, the electronic device 200 may display, in the virtual design space 1120, a first 3D model 1121 generated based on the first CAD Representation. In one embodiment, the first area 1101 may include not only the virtual design space 1120 but also a list 1110 of a plurality of design elements constituting the visualized first 3D model 1121. For example, the electronic device 200 may identify, based on the first CAD Representation, the plurality of design elements constituting the first 3D model 1121 and may generate the list 1110 listing the plurality of design elements. The generated list 1110 may be displayed on the first screen 1100a via the user device 10.

According to various embodiments, in operation 1003, the electronic device 200 may obtain a first user input for editing at least one first design element of the first 3D model via at least one of the first area and the second area. According to one embodiment, the first design element may include at least one of one or more parts or one or more portions constituting the first 3D model.

According to one embodiment, the electronic device 200 may obtain, via the first area 1101, a first user input 1122 for editing at least one first design element (e.g., a backrest and an armrest) of the first 3D model 1121. In one embodiment, when the electronic device 200 obtains a user input via the first area 1101, the electronic device 200 may obtain an input such as a mouse click, a drag, or a touch. For example, the electronic device 200 may obtain the first user input 1122 that selects an area of a backrest and an armrest of the first 3D model 1121 in order to modify a sofa backrest and an armrest of the first 3D model 1121.

According to one embodiment, the electronic device 200 may obtain, via the second area 1102, a first user input 1131 for editing at least one first design element (e.g., a backrest and an armrest) of the first 3D model 1121. In one embodiment, when the electronic device 200 obtains a user input via the second area 1102, the electronic device 200 may obtain an input such as text or file upload. For example, the electronic device 200 may obtain a text user input 1131 such as “Make the backrest and the armrest of the sofa integrated.”

According to various embodiments, the electronic device 200 may obtain a first user input 1122 and/or 1131 via the first area 1101 and the second area 1102. That is, the electronic device 200 may obtain user inputs by using both the first area 1101 and the second area 1102, and may edit the first 3D model 1121 based on the first user input obtained from each area. As various types of user inputs are obtained via a plurality of areas, the electronic device 200 may more accurately identify a user intent regarding editing of the first 3D model 1121.

According to various embodiments, in operation 1005, the electronic device 200 may obtain a second CAD Representation in which the first CAD Representation is edited based on the first user input.

Referring to FIG. 12, the electronic device 200 generates a second CAD Representation 1230 based on an obtained first user input 1210 (e.g., the first user inputs 1122 and/or 1131). In this case, generating a structured command 1220 to generate the second CAD Representation 1230 and generating a second 3D model 1240 may be similar to generating the structured command 730 described with reference to FIG. 7A to generate the CAD Representation 740 and generating the 3D model 750. Accordingly, redundant or similar descriptions may be omitted.

Referring to FIG. 12, the electronic device 200 may obtain a first user input 1210 (e.g., the first user inputs 1122 and/or 1131) for editing the first 3D model 1121 via the first area 1101 and/or the second area 1102.

According to one embodiment, the electronic device 200 may obtain, via the agent 310, a structured command 1220 by interpreting the first user input 1210. According to one embodiment, the structured command 1220 may be a command for generating a second CAD Representation 1230 in which the first CAD Representation for the first 3D model 1121 is edited based on the first user input 1210. For example, the structured command 1220 may be a prompt provided to an artificial intelligence model to generate the second CAD Representation 1230. According to one embodiment, the structured command 1220 may include at least one of natural language text indicating an editing operation of the first 3D model 1121, a shape of an edited 3D model, a target shape of the edited 3D model, a numerical constraint condition, part-wise relationship information, and material information.

According to various embodiments, the first user input 1210 may include an input for the virtual design space 1120 and a first list 1110 indicating a plurality of design elements constituting the first 3D model 1121. For example, the electronic device 200 may obtain the first user input 1210 via the virtual design space 1120 and the list 1110.

According to one embodiment, the electronic device 200 may identify, via the agent 310, a portion to be edited in the first CAD Representation for the first 3D model 1121 based on the first user input 1210. For example, the agent 310 may analyze the first user input 1210 and may identify at least one first design element (e.g., a backrest and an armrest) that needs to be edited in the first CAD Representation.

According to various embodiments, the electronic device 200 may obtain first coordinate information for a portion of the first 3D model 1121 that needs to be edited based on the first user input 1210. For example, the electronic device 200 may obtain the first user input 1210 that selects, from among a plurality of design elements included in the list 1110, at least one first design element that needs to be edited. For example, the electronic device 200 may obtain the first user input 1210 that selects, in the first 3D model 1121 displayed in the virtual design space 1120, at least one first design element that needs to be edited. Based on the first user input 1210, the electronic device 200 may obtain coordinate information for a portion to be edited (e.g., a backrest and an armrest). For example, the electronic device 200 may obtain information on coordinates at which the at least one first design element to be edited is displayed in the virtual design space 1120.

According to one embodiment, based on the coordinate information, the electronic device 200 may generate the structured command 1220 for generating the second CAD Representation 1230 in which the at least one first design element is edited.

According to one embodiment, the electronic device 200 may generate the second CAD Representation 1230 based on the structured command 1220. For example, the code generation model 320 may receive the structured command 1220 as an input. The code generation model 320 may interpret the received structured command 1220 and may generate and output the second CAD Representation 1230 as a corresponding output.

According to one embodiment, based on the first user input 1210, the electronic device 200 may obtain the second CAD Representation 1230 regenerated for a portion of the first CAD Representation that needs to be edited.

According to one embodiment, a method of generating the second CAD Representation 1230 may vary. For example, the code generation model 320 may identify a portion that needs to be edited in the first CAD Representation and may obtain the second CAD Representation 1230 in which only the portion that needs to be edited is edited. For example, the code generation model 320 may identify a portion that needs to be edited in the first CAD Representation and may obtain the second CAD Representation 1230 by regenerating only the portion that needs to be edited. Without being limited to the above examples, the electronic device 200 may analyze the first user input 1210 to identify at least one first design element (e.g., a backrest and an armrest) that needs to be edited in the first CAD Representation and may modify a parameter corresponding to the first design element. That is, the electronic device 200 may edit the first CAD Representation such that the second CAD Representation 1230 includes a parameter defining a new structure corresponding to a user intent.

According to various embodiments, in operation 1007, the electronic device 200 may obtain a visualized second 3D model by rendering the second CAD Representation. For example, the electronic device 200 may render, by using the rendering module 336, the second CAD Representation 1230 obtained via the code generation model 320. For example, the agent 310 may obtain the second CAD Representation 1230 from the code generation model 320 and may transfer the second CAD Representation 1230 to the rendering module 336. The rendering module 336 may receive the second CAD Representation 1230 as an input, may render the second CAD Representation 1230, and may output a visualized second 3D model 1240. The second 3D model 1240 may be a 3D model in which at least one first design element of the first 3D model 1121 is edited based on the first user input 1210.

According to various embodiments, in operation 1009, the electronic device 200 may display, via the user Device, a second screen displaying the visualized second 3D model in the first Area.

Referring to FIG. 11B, a second screen 1100b displaying a second 3D model 1123 in the first area 1101 is illustrated. According to one embodiment, the electronic device 200 may obtain the second 3D model 1123 (e.g., the second 3D model 1240) obtained by rendering the second CAD Representation 1230.

According to one embodiment, the second 3D model 1123 may be a model in which at least one first design element of the first 3D model 1121 is edited based on the first user input 1210. For example, based on the first user input 1210, the electronic device 200 may obtain the second CAD Representation 1230 in which a backrest and an armrest, which are at least one first design element, are edited. For example, the electronic device 200 may obtain the second CAD Representation 1230 configured to edit the backrest and the armrest to be integrated in the first 3D model 1121. The electronic device 200 may render the second CAD Representation 1230 to obtain the second 3D model 1123 in which the backrest and the armrest are configured to be integrated. In one embodiment, the electronic device 200 may display, via the user device 10, the second screen 1100b displaying the second 3D model 1123 in the virtual design space 1120.

According to various embodiments, the electronic device 200 may control the user device 10 such that a user is provided with various visual information regarding editing of the first 3D model 1121 on the second screen 1100b.

According to one embodiment, the electronic device 200 may provide, via the second screen 1100b, the list 1110 of a plurality of design elements together with the second 3D model 1123. The list 1110 may include a UI component that shows, in a text form, a list of design elements including individual parts or portions constituting the second 3D model 1123. Through the UI component indicating the plurality of design elements, a user may systematically identify an overall structure of the 3D model and may individually select and manage each element.

According to one embodiment, in order to provide feedback for the edited second 3D model 1123, the electronic device 200 may visually distinguish and display at least one first design element 1111 (e.g., a backrest and an armrest) edited in the list 1110 of the plurality of design elements. For example, the electronic device 200 may control the list 1110 such that an edited portion is distinguished and emphasized by applying a visual effect such as shading to a design element corresponding to the backrest and the armrest, which are portions modified compared to the conventional first 3D model 1121. Without being limited to the above example, the electronic device 200 may distinguish and display an edited design element through various methods.

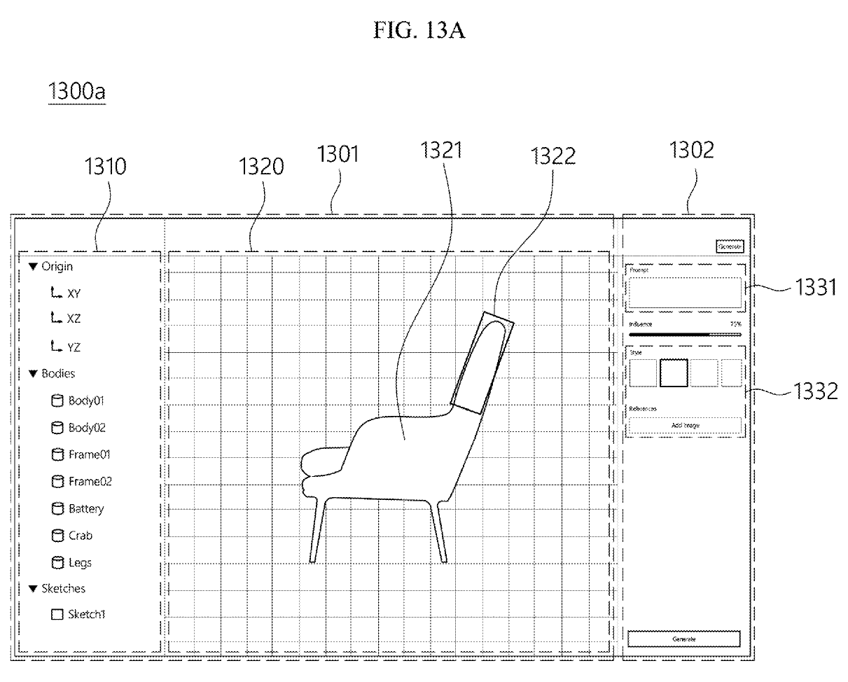

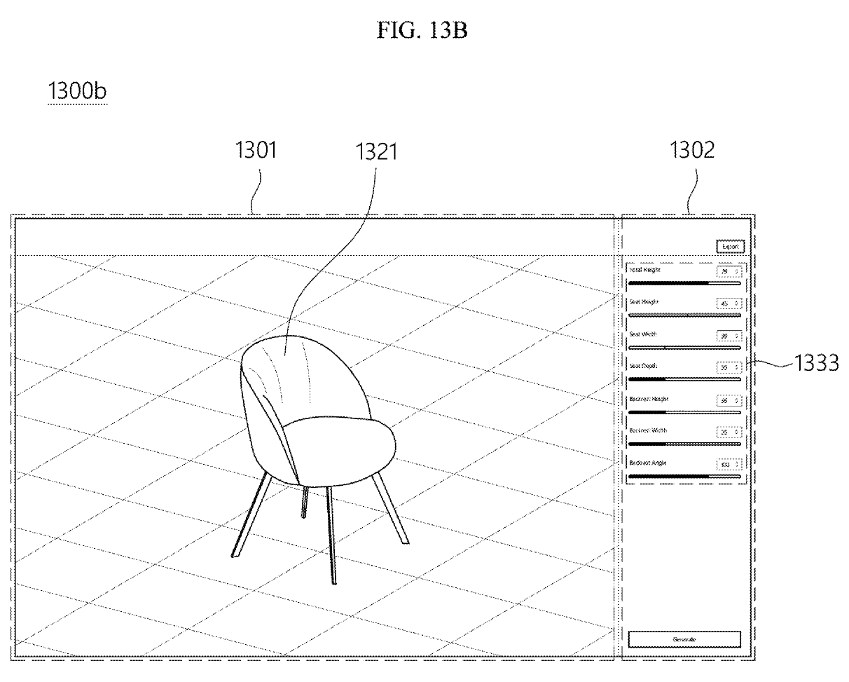

FIG. 13A is a diagram illustrating an example among various user interfaces for editing a 3D model according to various embodiments.

FIG. 13B is a diagram illustrating an example among various user interfaces for editing a 3D model according to various embodiments.

Referring to FIGS. 13A and 13B, various user input interfaces for editing a first 3D model 1321 generated based on a first CAD Representation are illustrated.

Referring to FIG. 13A, the electronic device 200 may display, via the user device 10, a screen 1300a for editing the first 3D model 1321.

According to one embodiment, the screen 1300a may include a first area 1301 including a virtual design space 1320 and a list 1310 of a plurality of design elements of the first 3D model 1321.

According to one embodiment, the screen 1300a may include a second area 1302 including a user prompt 1331 and a style selection area 1332.

According to various embodiments, the electronic device 200 may obtain various user inputs for editing the first 3D model 1321 via various user interfaces of the first area 1301 and the second area 1302. For example, a user may edit the first 3D model 1321 by selecting or combining intuitive and efficient input methods according to a preference of the user or a purpose of editing.

According to various embodiments, the electronic device 200 may obtain a user input via various user interfaces and may edit the first 3D model 1321.

According to one embodiment, the electronic device 200 may obtain a first user input 1322 in which the first 3D model 1321 rendered in the virtual design space 1320 of the first area 1301 is manipulated by using a mouse, a touch, or the like via the user device 10. For example, the electronic device 200 may obtain the first user input 1322 that selects a backrest of a chair, which is the first 3D model 1321, in order to edit the backrest of the chair.

Without being limited to the above example, the electronic device 200 may obtain, via the user device 10, a user input for selecting a specific part or portion as an input for the list 1310 of the plurality of design elements displayed in the first area 1301. The user input may be an input that may be obtained because the first 3D model 1321 is generated based on the first CAD Representation, and may be useful when a design element to be edited is hidden due to complexity of the first 3D model 1321 or when precise selection is required. The electronic device 200 may obtain, as an input for the list 1310 of the plurality of design elements, an editing-related input following the user input for selecting the specific part or portion.

In one embodiment, the electronic device 200 may obtain, via the user device 10, a user input for the user prompt 1331 of the second area 1302. For example, the electronic device 200 may obtain, through the user prompt 1331, an input for editing the first 3D model 1321, such as a natural language text input or a specific file upload input.

In one embodiment, the electronic device 200 may obtain, via the user device 10, a user input for the style selection area 1332 of the second area 1302. For example, the electronic device 200 may display a plurality of predefined styles through the style selection area 1332. When a user input for the style selection area 1332 is obtained for editing the first 3D model 1321, the electronic device 200 may apply, in a batch manner, a plurality of design parameters (e.g., shape, proportion, material, and/or a color combination) associated with a corresponding style to the entire first 3D model 1321 or to at least one designated first design element.

In one embodiment, when the user input is obtained through various methods as described above, the electronic device 200 may generate a structured command (e.g., the structured command 1220 of FIG. 12) for editing at least one first design element of the first 3D model 1321 based on the user input and may generate a second CAD Representation 1230 based on the structured command.

Referring to FIG. 13B, the electronic device 200 may display, via the user device 10, a screen 1300b for editing the first 3D model 1321.

According to one embodiment, the screen 1300b may include a numerical adjustment area 1333 in the second area 1302. However, the numerical adjustment area 1333 may be displayed in various areas of a screen without being limited to the illustrated example.

According to one embodiment, the electronic device 200 may display, via the user device 10, the numerical adjustment area 1333 for at least one design element of the first 3D model 1321. The numerical adjustment area 1333 may include a list of at least one design element constituting the first 3D model 1321 and a currently set numerical value for each design element. For example, the numerical adjustment area 1333 may include numerical values of parameters such as thickness, width, and/or angle for each of at least one design element constituting the first 3D model 1321.

According to one embodiment, the electronic device 200 may edit the first 3D model 1321 based on a user input for the numerical adjustment area 1333. For example, the electronic device 200 may obtain, via the user device 10, a user input for adjusting a numerical value of at least one design element for the numerical adjustment area 1333. For example, the electronic device 200 may obtain, via the user device 10, a user input for modifying a “thickness” parameter value of at least one design element. As a user interface for the modification, various graphic user interfaces may be used, such as direct input or an input for manipulating a graphic controller.

In one embodiment, when the user input is obtained, the electronic device 200 may generate a structured command (e.g., the structured command 1220 of FIG. 12) for adjusting a numerical value of a specific parameter of at least one design element of the first 3D model 1321 based on the user input and may generate a second CAD Representation 1230 based on the structured command.

According to various embodiments, the electronic device 200 may obtain a user input for deleting at least one first design element of the first 3D model 1321. For example, when the electronic device 200 obtains a user input for deleting at least one first design element of the first 3D model 1321, the electronic device 200 may obtain coordinate information for the at least one first design element based on the user input.

According to one embodiment, based on the coordinate information, the electronic device 200 may delete the at least one first design element in the first 3D model 1321 and may obtain a second CAD Representation in which a region of the deleted at least one first design element is regenerated. For example, based on the coordinate information, the electronic device 200 may generate a structured command for deleting the at least one first design element in the first 3D model 1321 and regenerating a region of the deleted at least one first design element, and may generate the second CAD Representation through the structured command.

In one embodiment, the electronic device 200 may render the second CAD Representation to visualize a second 3D model in which the at least one first design element is deleted from the first 3D model. Accordingly, the electronic device 200 may generate a second 3D model (e.g., the second 3D model 1240) in which at least one first design element is deleted from the first 3D model 1321.

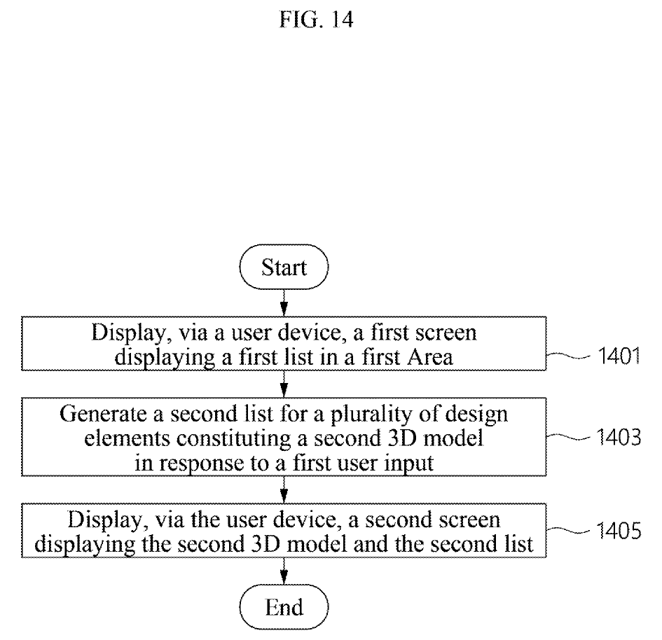

FIG. 14 is a flowchart illustrating an operation in which an electronic device provides a screen displaying an edited 3D model according to various embodiments.

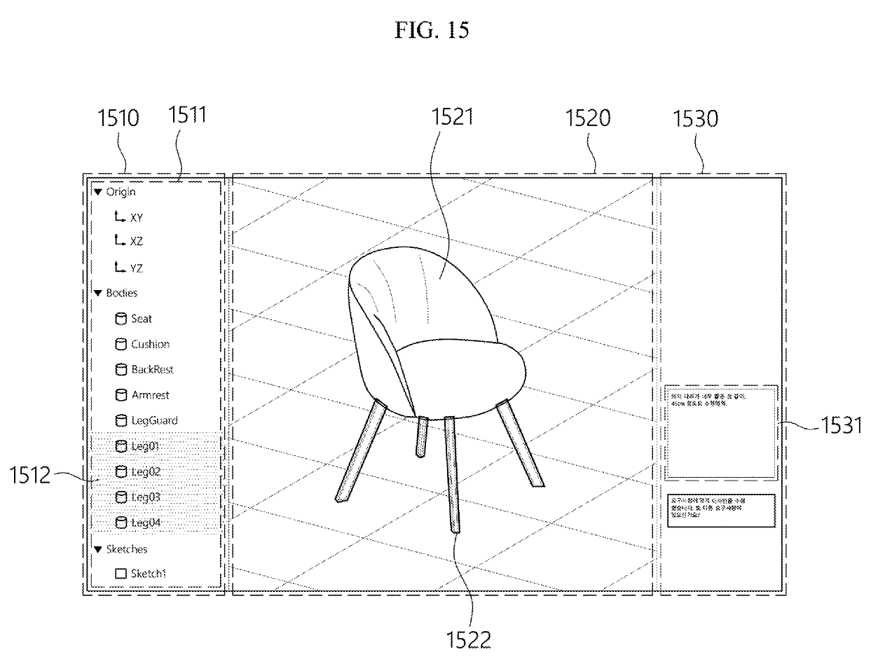

FIG. 15 is a diagram illustrating an example among various user interfaces for displaying an edited 3D model according to various embodiments.

Each of the operations described below may be performed in combination with each other. In addition, among the operations described below, an operation by the electronic device 200 (e.g., the electronic device 20 of FIG. 1 and the electronic device 200 of FIG. 2) may refer to an operation by a processor 210 (e.g., the processor 210 of FIG. 2) of the electronic device 200.

In addition, “information” described below may be interpreted as “data” or “signal,” and “data” may be understood as a concept including both analog data and digital data.

According to various embodiments, the operations shown in FIG. 14 are not limited to the illustrated order and may be performed in various orders. In addition, according to various embodiments, more operations than the operations shown in FIG. 14 may be performed, or at least one fewer operation may be performed.

Referring to FIG. 14, in operation 1401, the electronic device 200 may display, via a user device, a first screen displaying a first list in a first Area (e.g., the first list 1110 of FIG. 11) (e.g., the first area 1101 of FIG. 11) (e.g., the first screen 1100a of FIG. 11) via the user device 10. For example, the electronic device 200 may display, via the user device 10, a first screen displaying, in the first area, a first list for a plurality of design elements constituting a conventional first 3D model (e.g., the first 3D model 1121). For example, the electronic device 200 may display, via the user device 10, a first screen in which the plurality of design elements constituting the first 3D model are displayed as the first list, which is a hierarchical-structure text list.

According to various embodiments, in operation 1403, the electronic device 200 may generate a second list for a plurality of design elements constituting a second 3D model in response to a first user input.

Referring to FIG. 15, a screen displayed via the user device 10 and including a list area 1510, a virtual design space 1520, and a user prompt 1530 is illustrated.

According to one embodiment, the electronic device 200 may generate a second 3D model 1521 (e.g., the second 3D model 1240 of FIG. 12) for which editing is completed based on a first user input (e.g., the first user input 1210 of FIG. 12). For example, the electronic device 200 may obtain a first user input 1531 through the user prompt 1530 and may generate the second 3D model 1521 for which editing is completed based on the first user input 1531. In one embodiment, the electronic device 200 may generate a second list 1511 for a plurality of design elements constituting the second 3D model 1521. For example, the electronic device 200 may generate the second 3D model 1521 based on a second CAD Representation (e.g., the second CAD Representation 1230 of FIG. 12), and may generate the second list 1511 through the second CAD Representation 1230. The electronic device 200 may display the second list 1511 through the list area 1510.

According to various embodiments, in operation 1405, the electronic device 200 may display, via the user device, a second screen displaying the second 3D model and the second list via the user device 10. According to one embodiment, the electronic device 200 may display, via the user device 10, a second screen including the second 3D model 1521 for which editing is completed and the second list 1511 listing a plurality of design elements constituting the second 3D model 1521. That is, the electronic device 200 may display the second 3D model 1521 for which editing is completed in the virtual design space 1520, and may update and display the second list 1511 in which a structural change is reflected in the list area 1510. As such, as editing of the 3D model and updating of the list are synchronized, a user may immediately and clearly □□ how an editing □□ of the user is reflected in a structure of the model.

According to various embodiments, the electronic device 200 may provide a visual feedback function for enhancing user convenience during an editing process for a 3D model.

According to one embodiment, the electronic device 200 may identify at least one first design element activated as an editing target among a plurality of design elements constituting a first 3D model based on a first user input 1531 (e.g., the first user input 1210 of FIG. 12). For example, based on the first user input 1531 of “The chair legs seem too short. Please edit them to about 45 cm,” the electronic device 200 may identify four legs among the plurality of design elements constituting the first 3D model.

According to one embodiment, the electronic device 200 may display, via the user device 10, a first visual object (e.g., highlighting, outline display, or shading) for distinguishing the at least one first design element activated as the editing target among the plurality of design elements constituting the first 3D model. For example, the electronic device 200 may distinguishably display a portion corresponding to the at least one first design element of the first 3D model displayed in the virtual design space 1520. In addition, the electronic device 200 may distinguishably display a portion corresponding to the at least one first design element among the plurality of design elements of the first 3D model displayed in the list area 1510. Through this, an effect of preventing a user from accidentally editing an unintended element may be provided.

According to one embodiment, the electronic device 200 may provide a function of intuitively □□ an editing history even after editing is completed.

According to one embodiment, the electronic device 200 may identify at least one second design element, edited in the first 3D model based on the first user input 1531, among a plurality of design elements constituting the second 3D model 1521. Here, the at least one second design element may refer to at least one first design element that is edited after editing is completed when at least one first design element in the first 3D model becomes an editing target.

According to one embodiment, the electronic device 200 may display, via the user device 10, a second visual object distinguishing the at least one second design element. For example, the electronic device 200 may display, via the user device 10, visual objects 1512 and 1522 distinguishing, among the plurality of design elements constituting the second 3D model 1521, the at least one second design element edited in the first 3D model. For example, the electronic device 200 may display a visual object 1522 (e.g., an outline surrounding the at least one second design element) for distinguishing a portion corresponding to the at least one second design element of the second 3D model 1521. In addition, the electronic device 200 may display a visual object 1512 (e.g., shading for the at least one second design element) for distinguishing a portion corresponding to the at least one second design element among the plurality of design elements of the second 3D model displayed in the list area 1510. In one embodiment, based on a second user input for the second screen (e.g., view changes or a specific keyboard input), the electronic device 200 may display, via the user device, the second visual objects 1522 and 1512 distinguishing the at least one second design element in the second screen. Through this, a user may easily track and review which portion is changed in a complex model.

According to various embodiments, the electronic device 200 may provide various pieces of information related to editing without being limited to the above example. For example, the electronic device 200 may obtain, as a user input for the second screen displaying the second 3D model 1521, a user input for checking an editing history. In response to the user input, the electronic device 200 may provide detailed history information such as when, which parameter, and how it is changed, beyond simply visually indicating a changed portion. According to one embodiment, the electronic device 200 may provide the history information in various user interfaces in the form of text or a graph through a pop-up window or a separate panel.

According to one embodiment, when a user input for the history information is obtained, the electronic device 200 may provide a function of restoring and displaying 3D model information at a corresponding editing step.

For example, the electronic device 200 may provide a user with history information including a plurality of editing steps (e.g., Version 1.0: generate a base model, Version 1.1: change a leg shape, and Version 1.2: adjust a backrest angle) for a first 3D model. In this case, the electronic device 200 may obtain a user input for selecting a specific history item from the history information, for example, “Version 1.1: change a leg shape.”

In one embodiment, upon receiving such a user input, the electronic device 200 may load CAD Representation data at a past time point associated with the history item (i.e., CAD data in a “Version 1.1” state) from an internal storage. Thereafter, the electronic device 200 may render the loaded CAD Representation at the past time point and may display a 3D model of a corresponding version in the virtual design space 1520. Such a function may provide a user with robust version management and design exploration capabilities. A user may not only check an editing history as text, but may also directly visually □□ and compare a result of each editing step. In addition, when a current design is not satisfactory, the user may perform a “rollback” or “restore” operation to easily return to a desired past version at any time. This may provide a significant effect of greatly improving flexibility and stability in a design process.

FIG. 16 is a flowchart illustrating an operation in which an electronic device provides a plurality of 3D models based on a user input according to various embodiments.

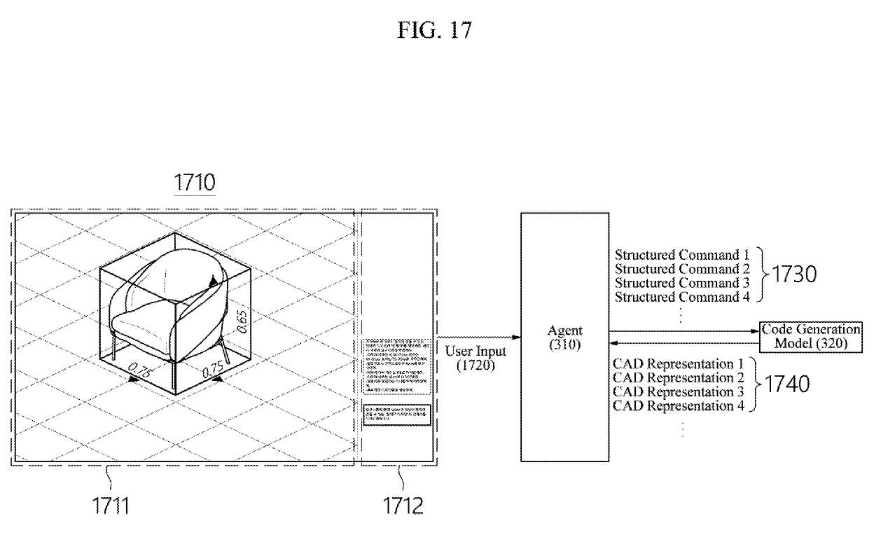

FIG. 17 is a diagram for describing that an electronic device generates a plurality of CAD Representations based on a user input according to various embodiments.

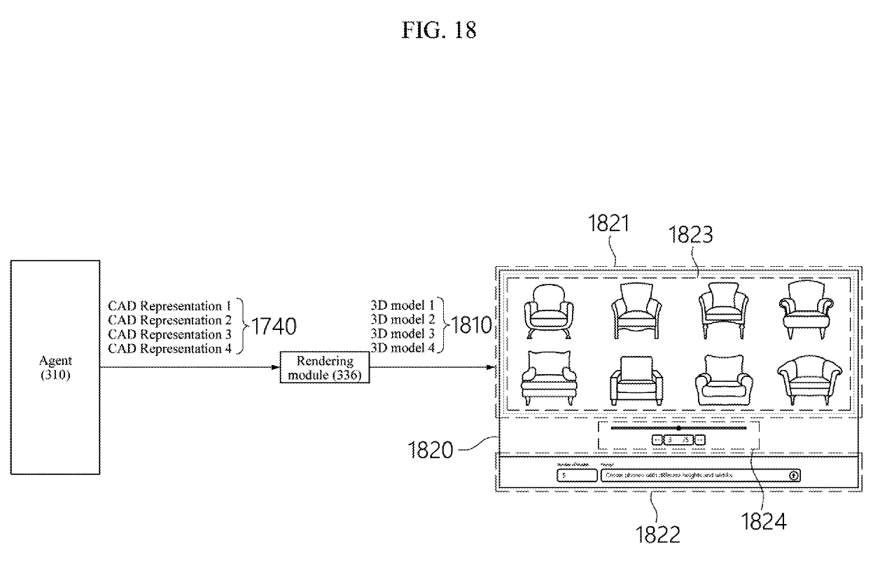

FIG. 18 is a diagram for describing that an electronic device provides a plurality of 3D models based on a plurality of CAD Representations according to various embodiments.

Each of the operations described below may be performed in combination with each other. In addition, among the operations described below, an operation by the electronic device 200 (e.g., the electronic device 20 of FIG. 1 and the electronic device 200 of FIG. 2) may refer to an operation by a processor 210 (e.g., the processor 210 of FIG. 2) of the electronic device 200.

In addition, “information” described below may be interpreted as “data” or “signal,” and “data” may be understood as a concept including both analog data and digital data.

According to various embodiments, the operations shown in FIG. 16 are not limited to the illustrated order and may be performed in various orders. In addition, according to various embodiments, more operations than the operations shown in FIG. 16 may be performed, or at least one fewer operation may be performed.

Referring to FIG. 16, in operation 1601, the electronic device 200 may display, via a user device, a first screen including a first area including a first virtual design space and a second area including a user prompt.

Referring to FIG. 17, the electronic device 200 may display, via the user device 10, a first screen 1710 including a first area 1711 including a first virtual design space and a second area 1712 including a user prompt.

According to various embodiments, in operation 1603, the electronic device 200 may obtain a user input for the first screen. According to one embodiment, the electronic device 200 may obtain a user input for generating a plurality of 3D models. According to various embodiments, the user input may include at least one of a text input, a 2D image input, a sketch input, a 3D data input, a bounding box input for the first virtual design space, a masking input for a specific region of the first virtual design space, and a sketch input, as an input for the plurality of 3D models to be generated.

According to one embodiment, the electronic device 200 may obtain a user input 1720 for the first screen 1710. For example, the electronic device 200 may obtain, as the user input 1720 for the first area 1711 and/or the second area 1712, a user input for generating a plurality of 3D models. In one embodiment, a method of obtaining the user input 1720 may be similar to the method of obtaining user inputs described above with reference to FIGS. 5 to 15. Accordingly, redundant descriptions may be omitted.

According to various embodiments, in operation 1605, the electronic device 200 may generate a plurality of CAD Representations based on the user input. According to one embodiment, the electronic device 200 may generate, via an agent 310, a plurality of structured commands 1730 for the user input 1720. The plurality of structured commands 1730 may be prompts provided to an artificial intelligence model (e.g., a code generation model 320) to generate a plurality of CAD Representations 1740.

According to one embodiment, the electronic device 200 may identify a user intent (e.g., generating a plurality of chairs) based on the user input 1720, and may generate a plurality of structured commands 1730 for generating the plurality of CAD Representations 1740 based on the user intent.

According to one embodiment, the electronic device 200 may identify the user intent based on the user input 1720 via the agent 310, and may generate a structured command according to the user intent. To generate the plurality of structured commands 1730, the electronic device 200 may additionally generate modified structured commands corresponding to the structured command. Accordingly, the electronic device 200 may generate the plurality of structured commands 1730 based on the structured command and the modified structured commands.

According to one embodiment, the electronic device 200 may generate the plurality of CAD Representations 1740. For example, the code generation model 320 may receive the plurality of structured commands 1730 as inputs. The code generation model 320 may interpret the received plurality of structured commands 1730 and may generate and output the plurality of CAD Representations 1740, which are final results respectively corresponding thereto.

According to various embodiments, in operation 1607, the electronic device 200 may o btain a plurality of visualized 3D models by rendering each of the plurality of CAD Representations.

According to various embodiments, in operation 1609, the electronic device 200 may display the plurality of visualized 3D models via the user device.

Referring to FIG. 18, the electronic device 200 may obtain, via a rendering module 336, a plurality of 3D models 1810 based on the plurality of CAD Representations 1740. For example, the agent 310 may obtain the plurality of CAD Representations 1740 from the code generation model 320 and may deliver the plurality of CAD Representations 1740 respectively to the rendering module 336. According to one embodiment, the rendering module 336 may receive the plurality of CAD Representations 1740 as inputs, render the plurality of CAD Representations 1740, and output a plurality of visualized 3D models 1810. A process of rendering a CAD Representation into a 3D model via the rendering module 336 may be similar to the process described with reference to FIGS. 7A and 7B. Accordingly, redundant or similar descriptions may be omitted.

According to various embodiments, the electronic device 200 may display the plurality of 3D models 1810 through a second design space 1821 distinguished from the first virtual design space. According to one embodiment, the first virtual design space may be a virtual space configured to display a single 3D model, and the second virtual design space may be a virtual space configured to display a plurality of 3D models.

According to one embodiment, based on generation of the plurality of 3D models 1810, the electronic device 200 may display, via the user device 10, a second screen 1820 distinguished from the first screen 1710 including the first area 1711 including the first virtual design space and the second area 1712 including the user prompt.

According to one embodiment, in response to generation of the plurality of 3D models 1810 while the first screen 1710 is displayed, the electronic device 200 may switch the first screen 1710 to the second screen 1820 to display the plurality of 3D models 1810. For example, the electronic device 200 may control the user device 10 to switch from the first screen 1710 to the second screen 1820 including the plurality of 3D models 1823 and display the second screen 1820. In one embodiment, the second screen 1820 may include a third area including the second virtual design space 1821 (e.g., the second virtual design space 1821 and the design exploration UI 1824). According to one embodiment, as the electronic device 200 switches from the first screen 1710 to the second screen 1820 via the user device 10, the first area 1711 of the first screen 1710 may be switched to the third area.

According to one embodiment, the electronic device 200 may generate the second virtual design space 1821 distinguished from the first virtual design space, and may display, via the user device 10, the second screen 1820 displaying a plurality of visualized 3D models 1823 in the second virtual design space 1821.

According to one embodiment, the electronic device 200 may display the plurality of 3D models 1823 in the second virtual design space 1821 in a carousel form or a horizontal scroll form of a user interface. However, the embodiments are not limited to the above example, and the electronic device 200 may display the plurality of 3D models 1823 via various forms of user interfaces. For example, the electronic device 200 may arrange a specific 3D model at a center in the second virtual design space 1821 and may display remaining 3D models in a thumbnail form of a smaller size.

According to one embodiment, the electronic device 200 may additionally display, via the user device 10, a design exploration UI 1824 for assisting display of the plurality of 3D models 1823. For example, the electronic device 200 may additionally display the design exploration UI 1824 configured to obtain a user input such as left/right arrow button inputs or a swipe operation. Based on a user input for the design exploration UI 1824, a 3D model displayed in the second virtual design space 1821 may be changed.

According to one embodiment, the second area 1712 including the user prompt in the first screen 1710 may be displayed in another area 1822 distinguished from the second virtual design space 1821 in the second screen 1820. However, the embodiments are not limited to the illustrated example, and the user prompt may be displayed in various areas distinguished from the second virtual design space 1821 (e.g., left, right, top, bottom, or an overlap window).

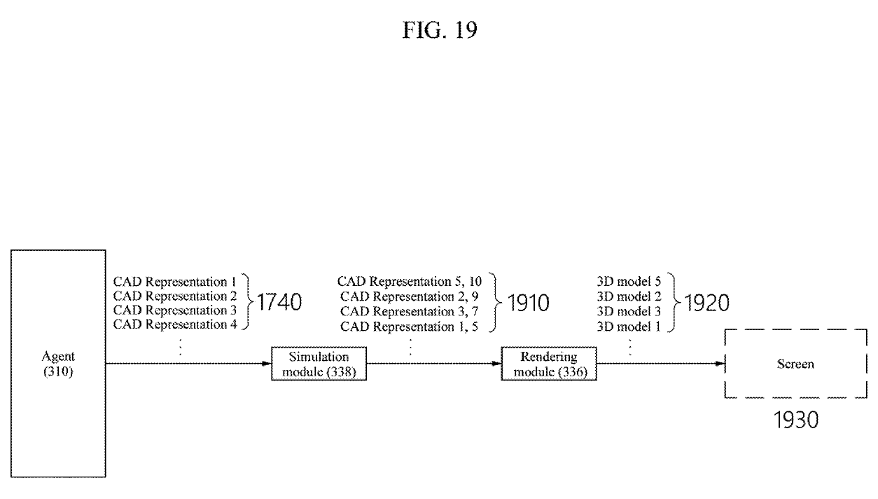

FIG. 19 is a diagram for describing that an electronic device arranges a plurality of 3D models according to various embodiments.

Referring to FIG. 19, the electronic device 200 may arrange a plurality of 3D models via a simulation module 338.

According to one embodiment, the electronic device 200 may generate a 3D model list in which the plurality of 3D models are arranged according to a specified condition. For example, the electronic device 200 may input the plurality of CAD Representations 1740 to the simulation module 338 to obtain an arranged CAD Representation list 1910 arranged according to the specified condition. For example, the electronic device 200 may input the plurality of CAD Representations 1740 to the simulation module 338 via the agent 310 to obtain the arranged CAD Representation list 1910.

According to one embodiment, depending on a type of the specified condition, the simulation module 338 may perform evaluation (e.g., CAE-based evaluation, BOM-based evaluation, and the like) for each of the generated plurality of CAD Representations 1740, and may calculate and output an evaluation score for each of the plurality of CAD Representations 1740. The agent 310 may obtain the arranged CAD Representation list 1910 based on the evaluation score for each of the plurality of CAD Representations 1740.

According to various embodiments, the type of the specified condition may vary. For example, the specified condition may include various scores such as an estimated manufacturing cost calculated based on a parts configuration and material information of a 3D model, structural stability evaluated through simulation applying a specific load condition, a size of the 3D model, and a suitability score with respect to a user intent.

According to one embodiment, the electronic device 200 may obtain the CAD Representation list 1910 in which the plurality of CAD Representations 1740 are arranged according to the specified condition, and may generate a 3D model list 1920 including a plurality of 3D models by rendering each CAD Representation included in the arranged CAD Representation list 1910.

In one embodiment, the electronic device 200 may display the plurality of 3D models via the user device 10 in the second virtual design space 1821. In this case, the electronic device 200 may control the user device 10 to display the plurality of 3D models in the second virtual design space 1821 based on the 3D model list 1920.

According to various embodiments, without being limited to the above example, the electronic device 200 may display the plurality of 3D models 1810 via a screen 1930 of the user device 10 in various manners.

According to one embodiment, the electronic device 200 may determine one 3D model among the plurality of 3D models 1810 according to the specified condition, and may display the determined 3D model as an activated and visually distinguished object from other 3D models. For example, the electronic device 200 may determine a specific 3D model among the plurality of CAD Representations 1740 according to the specified condition via the simulation module 338. For example, the electronic device 200 may determine, among the plurality of CAD Representations 1740, a first CAD Representation having a highest suitability with respect to the user intent via the simulation module 338. Subsequently, the electronic device 200 may generate the plurality of 3D models 1810 by rendering the plurality of CAD Representations 1740 respectively via the rendering module 336, and may control the user device 10 to display, on the screen 1930, a first 3D model corresponding to the first CAD Representation using a visually distinguished object. For example, the first 3D model may be distinguished by displaying the first 3D model in a larger size than other models, arranging the first 3D model at a center of the screen, and/or applying a highlight effect. Through this function, a user may immediately recognize an optimal design alternative recommended by the electronic device 200 and preferentially review the optimal design alternative.

FIG. 20 is a flowchart illustrating operations in which an electronic device provides design information for a 3D model according to various embodiments.

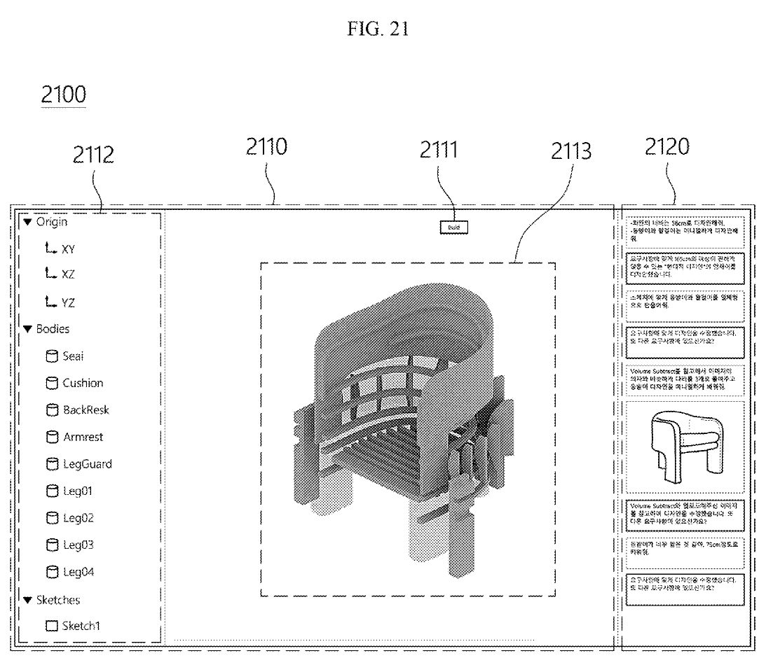

FIG. 21 is a diagram illustrating an example of various user interfaces for displaying design information of a 3D model according to various embodiments.

Each of the operations described below may be performed in combination with each other. In addition, among the operations described below, operations performed by the electronic device 200 (e.g., the electronic device 20 of FIG. 1 or the electronic device 200 of FIG. 2) may refer to operations performed by a processor 210 (e.g., the processor 210 of FIG. 2) of the electronic device 200.

In addition, the term “information” described below may be interpreted as “data” or “signal,” and “data” may be understood as a concept including both analog data and digital data.

According to various embodiments, the operations illustrated in FIG. 20 are not limited to the illustrated order and may be performed in various orders. In addition, according to various embodiments, more operations than those illustrated in FIG. 20 may be performed, or fewer than at least one operation may be performed.

Referring to FIG. 20, in operation 2001, the electronic device 200 may display, via the user device 10, a first screen displaying a first 3D model, generated based on a first CAD Representation, in a virtual design space.

According to one embodiment, in operation 2003, the electronic device 200 may obtain a first user input requesting design visualization information for the first 3D model. For example, the electronic device 200 may obtain, via the user device 10, a first user input on an icon requesting design visualization information of the first 3D model.

According to one embodiment, in operation 2005, the electronic device 200 may obtain, based on the first user input, design information for a plurality of design elements constituting the first 3D model via the first CAD Representation. The plurality of design elements may include at least one of one or more parts or one or more portions constituting the first 3D model.

According to one embodiment, the first CAD Representation may include a data structure in which GFL (Geometric Figure Library) objects are configured in a tree structure. For example, a CAD Representation for a chair model may have a hierarchical structure in which sub-component objects such as a “seat,” a “backrest,” and “legs” are connected as child nodes under a top-level object (root object) referred to as a “chair.”

According to one embodiment, the electronic device 200 may obtain detailed design information enabling identification of a structure and configuration of the generated first 3D model. For example, the electronic device 200 may obtain design information of the first 3D model based on the first CAD Representation that is based on mathematical parameters and relationships between components.

According to one embodiment, the design information may include information on at least one of an internal design or an external design for the plurality of design elements of the first 3D model.

For example, the electronic device 200 may obtain the design information by parsing the tree structure. For example, the electronic device 200 may obtain structural coupling information and individual configuration information among the plurality of design elements constituting the first 3D model. For example, the electronic device 200 may analyze parent-child relationships of the tree structure to identify how each design element (part) is assembled. For example, the electronic device 200 may clearly recognize that “legs” and a “backrest” are assembled as subordinate components to a “seat.” For example, the electronic device 200 may read data stored in each node (e.g., a “leg” object) to identify how the corresponding design element is configured. Each node may include unique shape information defined in the GFL (e.g., a cylinder), along with specific parameter values such as “length = 500 mm,” “thickness = 30 mm,” and “material = walnut.”

According to one embodiment, when the first CAD Representation is a text-based CAD code that mathematically defines NURBS (Non-Uniform Rational B-Spline) surfaces, the electronic device 200 may obtain design information by interpreting the corresponding code. That is, by analyzing functions and parameters described in the code, the electronic device 200 may identify how each surface of the 3D model is precisely generated based on a mathematical definition. For example, the first CAD Representation may include at least one function and parameter that mathematically define a shape represented by NURBS surfaces with respect to the first 3D model. In this case, the electronic device 200 may obtain design information for the plurality of design elements constituting the first 3D model based on the at least one function and the parameter.

As described above, the electronic device 200 may generate the first 3D model based on the first CAD Representation in response to a user input. In addition, the electronic device 200 may obtain design information for the first 3D model based on the first CAD Representation.

According to one embodiment, in operation 2007, the electronic device 200 may display, via the user device, a second screen including a first visual object representing design visualization information of at least some of the plurality of design elements based on the design information.

Referring to FIG. 21, the electronic device 200 may display, via the user device 10, a second screen 2100 including a first visual object 2113 representing design visualization information.

According to one embodiment, the electronic device 200 may display, via the user device 10, the second screen 2100 including a first area 2110 including a list 2112 of a plurality of design elements constituting the first 3D model and the first visual object 2113, and a second area 2120 including a user prompt.

According to one embodiment, the electronic device 200 may obtain, via the user device 10, a first user input on an icon 2111 requesting design visualization information of the first 3D model. In this case, the design visualization information may be provided to the user through various methods depending on a type of the icon 2111.

For example, the electronic device 200 may control the user device 10 such that the first visual object 2113, which represents design information of the first 3D model, is displayed not only as a static image but also dynamically. For example, the electronic device 200 may control the user device 10 to display the design information of the first 3D model as a video. That is, the visual object 2113 may be a video that dynamically displays an internal design or an external design of at least some of a plurality of design elements constituting the first 3D model.

For example, when the electronic device 200 obtains a user input requesting a cross-sectional view of the first 3D model, the electronic device 200 may play a cut-away animation in which the first 3D model is virtually cut to reveal an internal structure. In addition, when the electronic device 200 obtains a user input requesting an assembly process of the plurality of design elements of the first 3D model, the electronic device 200 may provide an explode/assemble video sequentially showing an assembly process of the plurality of design elements.

According to one embodiment, the electronic device 200 may display, via the user device 10, the list 2112 of the plurality of design elements constituting the first 3D model in the first area 2110. In this case, the electronic device 200 may group the plurality of design elements according to a specified criterion.

According to one embodiment, the plurality of design elements constituting the first 3D model may include a first sub-parts group. This may refer to grouping related parts into a single logical unit in order to manage a complex model and improve editing efficiency. For example, the electronic device 200 may obtain the first sub-parts group by grouping some of the plurality of design elements according to a specified criterion. The specified criterion may be determined not only by a user’s manual selection, but also by analyzing relationships among the plurality of design elements. In this case, the electronic device 200 may group at least some of the plurality of design elements based on at least one of a physical relationship, a functional relationship, or a semantic relationship among the plurality of design elements.

In one embodiment, the physical relationship may refer to a relationship between parts that are adjacent to or in contact with each other. The functional relationship may refer to a relationship between parts that perform a specific function. The semantic relationship may refer to a relationship in which parts share a common meaning or attribute, such as using the same material or being manufactured through the same process.

According to one embodiment, the electronic device 200 may generate parts grouping information by grouping the plurality of design elements according to the specified criterion. The electronic device 200 may control the user device 10 to display the parts grouping information in association with the virtual design space. For example, when displaying the first 3D model in the virtual design space, the electronic device 200 may display the first 3D model using visually distinguished objects for each grouped part based on the parts grouping information, or may control the visually distinguished objects for each grouped part to be displayed according to a user input.

According to one embodiment, the electronic device 200 may obtain, via the user device 10, a request for design information for the first sub-parts group by grouping some of the plurality of design elements of the first 3D model according to the specified criterion. That is, the electronic device 200 may provide not only design information for the entire first 3D model, but also design information for the first sub-parts group.

For example, when the specified criterion is a physical relationship, the electronic device 200 may generate a plurality of sub-parts groups by grouping a plurality of parts included in the plurality of design elements based on whether the plurality of parts are coupled to each other. In this case, the grouping information may include information on the plurality of sub-parts groups grouped based on coupling relationships among the plurality of parts. In one embodiment, the electronic device 200 may display, via the user device 10, information on the plurality of sub-parts groups on the first screen. When a user input on the parts grouping information is obtained, the electronic device 200 may identify the user input as an input requesting design visualization information for at least some of the plurality of sub-parts groups.

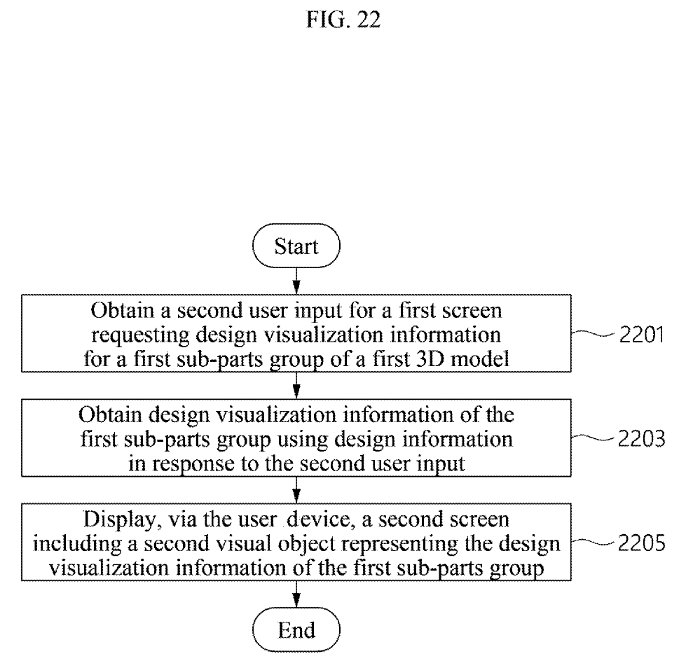

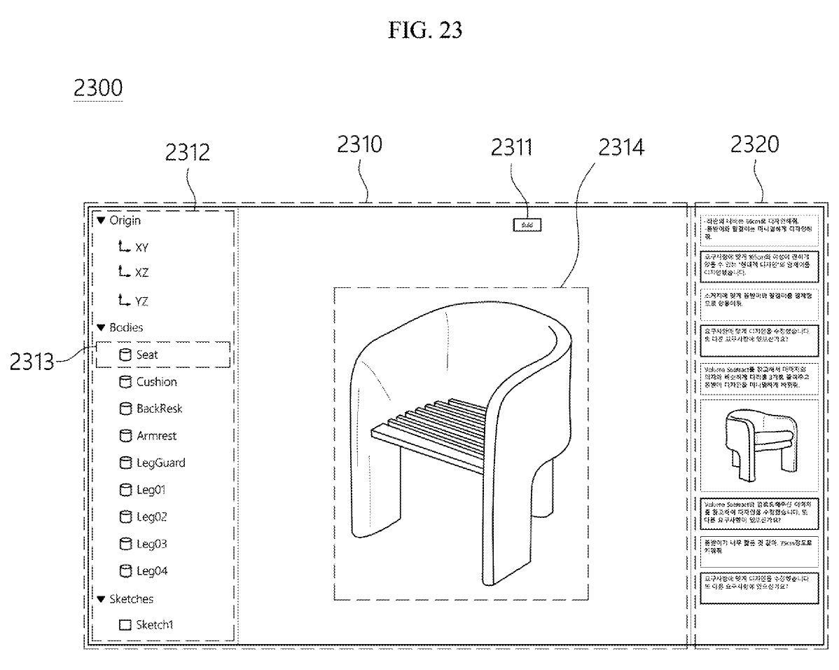

Providing design information for a sub-parts group by the electronic device 200 will be described later with reference to FIGS. 22 and 23.

FIG. 22 is a flowchart illustrating an operation in which an electronic device provides design information for a portion of a 3D model according to various embodiments.

FIG. 23 is a diagram illustrating one example of various user interfaces for displaying design information for a portion of a 3D model according to various embodiments.

Each of the operations described below may be performed in combination with one another. In addition, among the operations described below, operations performed by the electronic device 200 (e.g., the electronic device 20 of FIG. 1 or the electronic device 200 of FIG. 2) may be understood as operations performed by a processor 210 of the electronic device 200 (e.g., the processor 210 of FIG. 2).

In addition, the term “information” described below may be interpreted as “data” or “signal,” and the term “data” may be understood as including both analog data and digital data.

According to various embodiments, the operations illustrated in FIG. 22 are not limited to the illustrated order and may be performed in various orders. In addition, according to various embodiments, more operations than those illustrated in FIG. 22 may be performed, or at least one fewer operation may be performed.

Referring to FIG. 22, in operation 2201, the electronic device 200 may obtain a second user input for a first screen requesting design visualization information for a first sub-parts group of a first 3D model. For example, the electronic device 200 may obtain a second user input requesting design visualization information for a first sub-parts group (e.g., a chair) among a plurality of design elements constituting the first 3D model.

According to one embodiment, the electronic device 200 may generate parts grouping information by grouping the plurality of design elements according to a designated criterion. For example, the electronic device 200 may group a plurality of parts constituting the plurality of design elements according to a designated criterion and display the parts grouping information via the user device 10. According to various embodiments, the second user input may be obtained as an input for the parts grouping information displayed via the user device 10 (e.g., an input for the first sub-parts group).

According to various embodiments, in operation 2203, the electronic device 200 may obtain design visualization information of the first sub-parts group using design information in response to the second user input.

According to various embodiments, in operation 2205, the electronic device 200 may display, via the user device 10, a second screen including a second visual object representing the design visualization information of the first sub-parts group.

Referring to FIG. 23, a second screen 2300 including a second visual object 2314 is illustrated. According to one embodiment, the electronic device 200 may display the second screen 2300 via the user device 10. In one embodiment, the second screen 2300 may include a first area 2310 including a list 2312 for a plurality of design elements of the first 3D model and the second visual object 2314, and a second area 2320 including a user prompt.

According to one embodiment, the list 2312 for the plurality of design elements may be displayed based on parts grouping information. For example, the list 2312 may be displayed based on grouped sub-parts groups (e.g., seat, cushion, backrest) obtained by grouping the plurality of design elements constituting the first 3D model according to a designated criterion.

According to one embodiment, the electronic device 200 may obtain, via the user device 10, a user input requesting design visualization information for a sub-parts group of the first 3D model as an input for a sub-parts group displayed in the list 2312. For example, when a user input for a first sub-parts group (e.g., seat) and a user input requesting design visualization information are obtained, the electronic device 200 may provide design visualization information for the first sub-parts group.

According to one embodiment, the electronic device 200 may obtain, via the user device 10, a second user input for an icon 2311 requesting design visualization information for the first sub-parts group of the first 3D model. In this case, depending on a type of the icon 2311, the design visualization information may be provided to a user in various manners. For example, when the electronic device 200 obtains a user input selecting the first sub-parts group (e.g., seat) in the list 2312 and a user input for the icon 2311 (build), the electronic device 200 may obtain design visualization information for the first sub-parts group. For example, the electronic device 200 may obtain design visualization information for the first sub-parts group using design information for the plurality of design elements as a whole, and may display, via the user device 10, the second visual object 2314 representing the design visualization information of the first sub-parts group.

In the present disclosure, each of the phrases “A or B,” “at least one of A and B,” “at least one of A or B,” “A, B, or C,” “at least one of A, B, and C,” and “at least one of A, B, or C” may include any one of the listed items or all possible combinations thereof.

Terms such as “first,” “second,” “primary,” or “secondary” may be used merely to distinguish one component from another and do not limit the components in any other aspect (e.g., importance or order).

In various embodiments of the present disclosure, terms such as “unit” or “module” may include a unit implemented in hardware, software, or firmware, and may be used interchangeably with terms such as logic, logic block, component, or circuit. A module may be a single component or a minimum unit or a portion thereof that performs one or more functions. A module may be implemented by various programs stored in an addressable storage medium and executable by a processor.

Various embodiments of the present disclosure may be implemented as software (e.g., programs) including one or more instructions stored in a memory 230 readable by a device (e.g., the electronic device 200). The memory 230 may be represented as a storage medium.

According to one embodiment, a method according to various embodiments disclosed herein may be provided as being included in a computer program product. The computer program product may be traded between a seller and a buyer as a commodity. The computer program product may be distributed in the form of a device-readable storage medium (e.g., a CD-ROM) or distributed online (e.g., via download or upload) through an application store or directly between two user devices.

According to various embodiments, each of the components described above (e.g., modules or programs) may include a single entity or multiple entities, and some of the multiple entities may be separately disposed in other components. According to various embodiments, one or more components or operations among the above-described components or operations may be omitted, or one or more other components or operations may be added. Additionally or alternatively, a plurality of components may be integrated into a single component. In such a case, the integrated component may perform one or more functions of each of the plurality of components in a same or similar manner as performed by the corresponding components prior to integration.

According to various embodiments, operations performed by modules, programs, or other components may be executed sequentially, in parallel, repeatedly, or heuristically, or one or more of the operations may be executed in a different order, omitted, or additional operations may be added.

Methods according to embodiments described in the claims or the specification of the present disclosure may be implemented in the form of hardware, software, or a combination thereof.

When implemented as software, a computer-readable storage medium storing one or more programs (software modules) may be provided. One or more programs stored in the computer-readable storage medium may be configured to be executable by one or more processors in an electronic device. One or more programs may include instructions that cause the electronic device to perform methods according to embodiments described in the claims or the specification of the present disclosure.

In the present disclosure, functions or operations performed by an electronic device may be performed by one or more processors executing one or more instructions stored in a memory. The processor may include at least one of a central processing unit (CPU), a graphics processing unit (GPU), a micro controller unit (MCU), a sensor hub, a supplementary processor, a communication processor, an application processor, an application-specific integrated circuit (ASIC), a field programmable gate array (FPGA), a neural processing unit (NPU), a system on chip (SoC), or an integrated circuit, and may include multiple cores.

Programs (software modules or software) may be stored in random access memory (RAM), non-volatile memory including flash memory, read-only memory (ROM), electrically erasable programmable read-only memory (EEPROM), magnetic disk storage devices, CD-ROMs, DVDs, other types of optical storage devices, magnetic cassettes, or a memory including any combination thereof. The memory may include a single storage medium or a combination of multiple storage media, and one or more instructions may be stored in a single storage medium or distributed across multiple storage media.

1. An electronic device comprising:
a communication circuit configured to transmit and receive data with a user device;
at least one processor; and
a memory storing instructions,
wherein the instructions are executed individually or collectively by the at least one processor to cause the electronic device to:
display, via the user device, a first screen including a first area including a first 3D model generated based on a first CAD Representation and a second area including a user prompt;
obtain a first user input for editing at least one first design element of the first 3D model via at least one of the first area and the second area, wherein the first design element includes at least one of one or more parts or one or more portions constituting the first 3D model;
obtain a second CAD Representation in which the first CAD Representation is edited based on the first user input;
obtain a second 3D model visualized by rendering the second CAD Representation; and
display, via the user device, a second screen displaying the visualized second 3D model in the first area.

2. The electronic device of claim 1,
wherein the first area includes a virtual design space for displaying a visualized 3D model and a list for a plurality of design elements constituting the 3D model.

3. The electronic device of claim 2,
wherein the instructions are executed individually or collectively by the at least one processor to cause the electronic device to:
identify a portion to be edited in the first CAD Representation based on the first user input; and
obtain the second CAD Representation regenerated for the portion to be edited in the first CAD Representation based on the first user input.

4. The electronic device of claim 3,
wherein the instructions are executed individually or collectively by the at least one processor to cause the electronic device to:
generate a structured command for editing the first 3D model based on the first user input; and
obtain the second CAD Representation based on the structured command.

5. The electronic device of claim 4,
wherein the first user input includes an input for the virtual design space and a first list representing a plurality of design elements constituting the first 3D model, and
wherein the instructions are executed individually or collectively by the at least one processor to cause the electronic device to:
obtain a first coordinate information for a portion to be edited in the first 3D model based on the input; and
generate the structured command based on the first coordinate information.

6. The electronic device of claim 4,
wherein the instructions are executed individually or collectively by the at least one processor to cause the electronic device to:
obtain the second CAD Representation according to inputting the structured command into a code generation model,
wherein the code generation model is an artificial intelligence model trained to output a text-based sequential code comprising functions or parameters defining CAD components based on the structured command.

7. The electronic device of claim 2,
wherein the instructions are executed individually or collectively by the at least one processor to cause the electronic device to:
display, via the user device, the first screen displaying the first list in the first area;
generate a second list for a plurality of design elements constituting the second 3D model in response to the first user input; and
display, via the user device, the second screen displaying the second 3D model and the second list.

8. The electronic device of claim 1,
wherein the instructions are executed individually or collectively by the at least one processor to cause the electronic device to:
identify, based on the first user input, at least one first design element activated as an editing target among a plurality of design elements constituting the first 3D model; and
display, via the user device, a first visual object for distinguishing the at least one first design element on the first screen.

9. The electronic device of claim 1,
wherein the instructions are executed individually or collectively by the at least one processor to cause the electronic device to:
identify, based on the first user input, at least one second design element edited from the first 3D model among a plurality of design elements constituting the second 3D model; and
display, via the user device, a second visual object for distinguishing the at least one second design element on the second screen based on a second user input for the second screen.

10. The electronic device of claim 9,
wherein the instructions are executed individually or collectively by the at least one processor to cause the electronic device to:
If the second user input includes a user input requesting to check an editing history for the second 3D model displayed in the first area, provide history information on editing of the second 3D model via the user device based on the second user input.

11. The electronic device of claim 1,
wherein the instructions are executed individually or collectively by the at least one processor to cause the electronic device to:
if the first user input is an input for deleting the at least one first design element:
obtain second coordinate information for the at least one first design element based on the first user input;
delete the at least one first design element from the first 3D model based on the second coordinate information and obtain the second CAD Representation in which a region of the deleted at least one first design element is regenerated; and
visualize the second 3D model in which the at least one first design element is deleted from the first 3D model by rendering the second CAD Representation.

12. A method of operating an electronic device, the method comprising:
displaying, via a user device, a first screen including a first area including a first 3D model generated based on a first CAD Representation and a second area including a user prompt;
obtaining a first user input for editing at least one first design element of the first 3D model via at least one of the first area and the second area,
wherein the first design element includes at least one of one or more parts or one or more portions constituting the first 3D model;
obtaining a second CAD Representation in which the first CAD Representation is edited based on the first user input;
obtaining a second 3D model visualized by rendering the second CAD Representation; and
displaying, via the user device, a second screen displaying the visualized second 3D model in the first area.

13. The method of claim 12,
wherein the first area includes a virtual design space for displaying a visualized 3D model and a list for a plurality of design elements constituting the 3D model.

14. The method of claim 13,
wherein the first user input includes an input for the virtual design space and a first list representing a plurality of design elements constituting the first 3D model, and
wherein obtaining the second CAD Representation comprises:
obtaining first coordinate information for a portion to be edited in the first 3D model based on the input;
generating a structured command based on the first coordinate information; and
obtaining the second CAD Representation based on the structured command.

15. The method of claim 14,
wherein obtaining the second CAD Representation further comprises:
obtaining the second CAD Representation according to inputting the structured command into a code generation model,
wherein the code generation model is an artificial intelligence model trained to output a text-based sequential code comprising functions or parameters defining CAD components based on the structured command.

16. The method of claim 13, further comprising:
displaying, via the user device, the first screen displaying the first list in the first area;
generating a second list for a plurality of design elements constituting the second 3D model in response to the first user input; and
displaying, via the user device, the second screen displaying the second 3D model and the second list.

17. The method of claim 12, further comprising:
identifying, based on the first user input, at least one first design element activated as an editing target among a plurality of design elements constituting the first 3D model; and
displaying, via the user device, a first visual object for distinguishing the at least one first design element on the first screen.

18. The method of claim 12, further comprising:
identifying, based on the first user input, at least one second design element edited from the first 3D model among a plurality of design elements constituting the second 3D model; and
displaying, via the user device, a second visual object for distinguishing the at least one second design element on the second screen based on a second user input for the second screen.

19. A computer-readable recording medium storing one or more programs including instructions for performing the method of claim 12.
